(19) United States
(12) Patent Application Publication
(10) Pub. No.: US 2024/0429222 A1
(43) Pub. Date: Dec. 26, 2024

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: Jing Cheng LIN, Suwon-si (KR); Youngkun Jee, Suwon-si (KR)

(73) Assignee: SAMSUNG ELECTRONICS CO., LTD., Suwon-si (KR)

(21) Appl. No.: 18/654,758

(22) Filed: May 3, 2024

(30) Foreign Application Priority Data
Jun. 26, 2023 (KR) 10-2023-0082189

(51) Int. Cl. H01L 25/00; H01L 21/56; H01L 23/00; H01L 23/367; H01L 23/538; H01L 25/065; H01L 25/18; H10B 80/00

(52) U.S. Cl. CPC H01L 25/50; H01L 21/56; H01L 23/367; H01L 23/5386; H01L 24/05; H01L 24/06; H01L 24/08; H01L 24/13; H01L 24/29; H01L 24/32; H01L 24/80; H01L 24/83; H01L 25/0652; H01L 25/18; H10B 80/00; H01L 2224/0557; H01L 2224/05605; H01L 2224/05609; H01L 2224/05611; H01L 2224/05623; H01L 2224/05624; H01L 2224/05638; H01L 2224/05639; H01L 2224/05644; H01L 2224/05647; H01L 2224/05649; H01L 2224/05655; H01L 2224/05657; H01L 2224/05664; H01L 2224/05666; H01L 2224/05671; H01L 2224/05676; H01L 2224/0568; H01L 2224/05681; H01L 2224/05683; H01L 2224/05684; H01L 2224/06181; H01L 2224/08145; H01L 2224/08225; H01L 2224/13111; H01L 2224/13139; H01L 2224/13147; H01L 2224/13155; H01L 2224/29186; H01L 2224/32225; H01L 2224/32245; H01L 2224/80379; H01L 2224/80896; H01L 2224/83896; H01L 2924/01004; H01L 2924/0504; H01L 2924/0544; H01L 2924/059; H01L 2924/0665; H01L 2924/07025; H01L 2924/1431; H01L 2924/1432; H01L 2924/14335; H01L 2924/1436; H01L 2924/1437; H01L 2924/1441; H01L 2924/1443

(57) ABSTRACT

A method of manufacturing a semiconductor package includes bonding a first semiconductor chip and a bridge structure onto a carrier structure; bonding a second semiconductor chip and a third semiconductor chip onto the bridge structure, the second semiconductor chip and the third semiconductor chip being apart from each other in a horizontal direction; and forming a plurality of connection bumps on the second semiconductor chip and the third semiconductor chip.

### CROSS-REFERENCE TO RELATED APPLICATION

This application is based on and claims priority under 35 U.S.C. § 119 to Korean Patent Application No. 10-2023-0082189, filed on Jun. 26, 2023, in the Korean Intellectual Property Office, the disclosure of which is incorporated by reference herein in its entirety.

### BACKGROUND

Embodiments of the present disclosure relate to a semiconductor package and a method of manufacturing the semiconductor package, and more particularly, to a semiconductor package including a bridge structure, and a method of manufacturing the semiconductor package.

As electronic technology has been developed, electronic devices have gradually become smaller, more multi-functional, and larger in capacity, and accordingly, high integration and high speed of semiconductor packages have also been required. To this end, a semiconductor package including a plurality of semiconductor chips stacked and/or arranged has been developed.

### SUMMARY

Embodiments of the present disclosure provide a semiconductor package which includes a bridge structure that connects different semiconductor chips together and in which heat dissipation characteristics and structural stability are ensured.

Embodiments of the present disclosure provide a method of manufacturing a semiconductor package which includes a bridge structure that connects different semiconductor chips together and in which manufacturing costs are reduced.

According to embodiments of the present disclosure, a method of manufacturing a semiconductor package is provided and includes: bonding a first semiconductor chip and a bridge structure onto a carrier structure bonding a second semiconductor chip and a third semiconductor chip onto the bridge structure, the second semiconductor chip and the third semiconductor chip being apart from each other in a horizontal direction; and forming a plurality of connection bumps on the second semiconductor chip and the third semiconductor chip.

According to embodiments of the present disclosure, a method of manufacturing a semiconductor package is provided and includes: bonding a bridge chip and a plurality of dummy structures onto a carrier structure; connecting a first semiconductor chip to a second semiconductor chip through the bridge chip by bonding the first semiconductor chip and the second semiconductor chip onto the bridge chip; forming a cover insulating layer that covers the first semiconductor chip and the second semiconductor chip; forming a plurality of connection vias that pass through the cover insulating layer to contact the first semiconductor chip or the second semiconductor chip; and forming a plurality of connection bumps on the cover insulating layer, the plurality of connection bumps being in contact with the plurality of connection vias.

According to embodiments of the present disclosure, a method of manufacturing a semiconductor package is provided and includes: bonding a first semiconductor chip, a bridge structure, and a plurality of dummy structures onto a carrier structure, the plurality of dummy structures being around the first semiconductor chip and the bridge structure; forming a first preliminary gap-fill insulating layer that covers the first semiconductor chip, the bridge structure, and the plurality of dummy structures; forming a first gap-fill insulating layer that exposes the first semiconductor chip, the bridge structure, and the plurality of dummy structures, by planarizing the first preliminary gap-fill insulating layer; bonding, onto the bridge structure, a second semiconductor chip and a third semiconductor chip, such that the second semiconductor chip is connected to the third semiconductor chip via the bridge structure; forming a second preliminary gap-fill insulating layer that covers the second semiconductor chip and the third semiconductor chip; forming a second gap-fill insulating layer that exposes the second semiconductor chip and the third semiconductor chip, by planarizing the second preliminary gap-fill insulating layer; forming a cover insulating layer on the second semiconductor chip, the third semiconductor chip, and the second gap-fill insulating layer; forming a plurality of connection vias that pass through the cover insulating layer and are connected to the second semiconductor chip or the third semiconductor chip; forming a plurality of connection bumps on the cover insulating layer, the plurality of connection bumps being respectively connected to the plurality of connection vias; and forming a heat dissipation structure by processing the carrier structure.

### BRIEF DESCRIPTION OF DRAWINGS

Embodiments of the present disclosure will be more clearly understood from the following detailed description taken in conjunction with the accompanying drawings in which:

FIG. 1A is a plan view of a semiconductor package according to embodiments;

FIG. 1B is a cross-sectional view taken along line X1-X1′ in FIG. 1A;

FIG. 2A is a plan view of a semiconductor package according to embodiments;

FIG. 2B is a cross-sectional view taken along line X2-X2′ in FIG. 2A;

FIG. 3 is a flowchart of a method of manufacturing a semiconductor package, according to embodiments;

FIGS. 4A to 4J are cross-sectional views illustrating a method of manufacturing a semiconductor package, according to embodiments;

FIGS. 5A to 5D are cross-sectional views illustrating a method of

manufacturing a semiconductor package, according to embodiments; and

FIGS. 6A and 6B are cross-sectional views illustrating a method of manufacturing a semiconductor package, according to embodiments.

### DETAILED DESCRIPTION

Hereinafter, non-limiting example embodiments are described in detail with reference to the accompanying drawings. In the drawings, the same reference character is used for the same element, and redundant descriptions thereof may be omitted.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

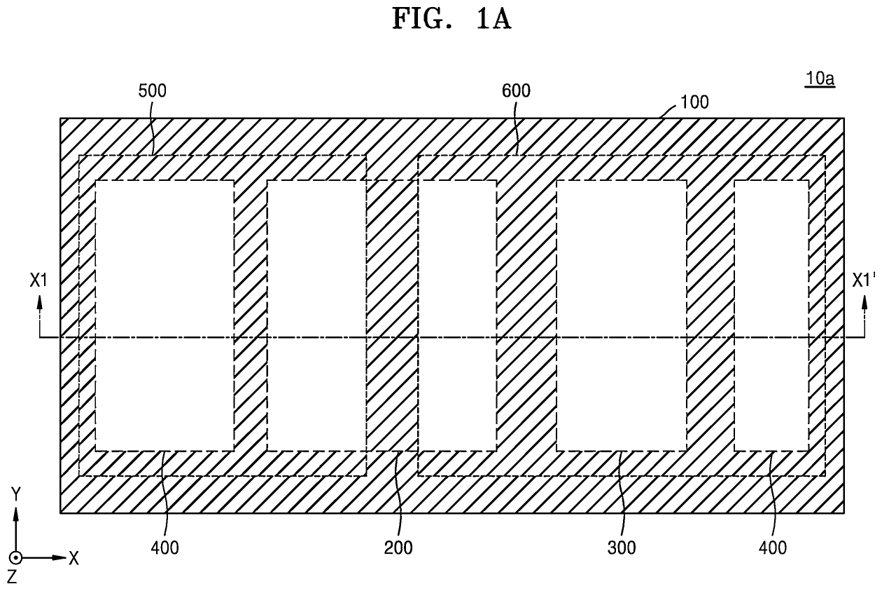

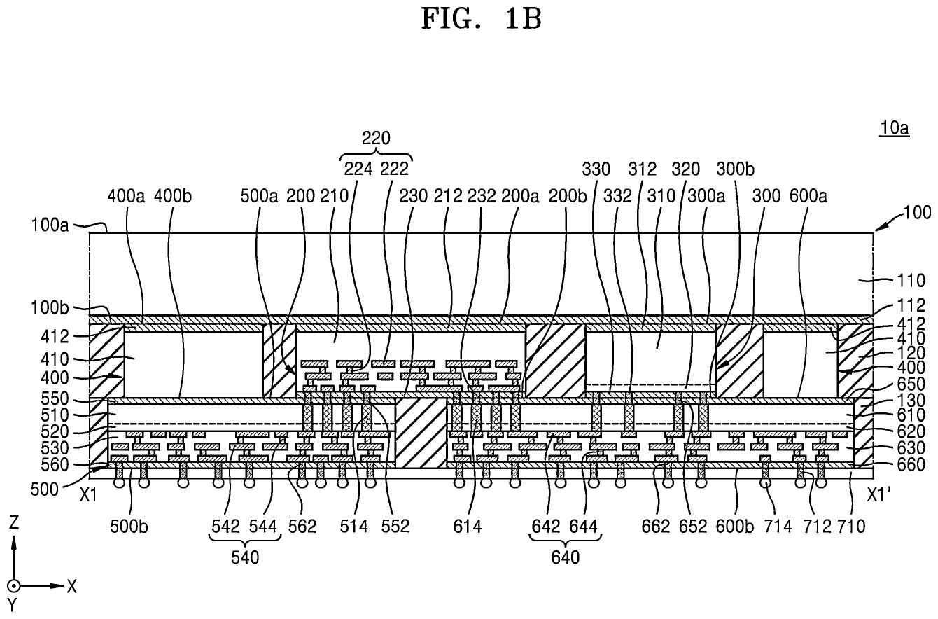

FIG. 1A is a plan view of a semiconductor package 10a according to embodiments. FIG. 1B is a cross-sectional view taken along line X1-X1′ in FIG. 1A.

Referring to FIGS. 1A and 1B, the semiconductor package 10a may include a heat dissipation structure 100, a bridge structure 200, a first semiconductor chip 300, a plurality of dummy structures 400, a second semiconductor chip 500, a third semiconductor chip 600, and a cover insulating layer 710.

According to embodiments, the second semiconductor chip 500 and the third semiconductor chip 600 may be spaced apart from each other on the cover insulating layer 710, and may be electrically connected to each other through the bridge structure 200 disposed on the second semiconductor chip 500 and the third semiconductor chip 600. The first semiconductor chip 300 may be disposed on the third semiconductor chip 600 and electrically connected to the third semiconductor chip 600. According to embodiments, the heat dissipation structure 100 may be disposed on the bridge structure 200 and the first semiconductor chip 300.

According to embodiments, the plurality of dummy structures 400 around the bridge structure 200 and the first semiconductor chip 300 may be disposed on the second semiconductor chip 500 and the third semiconductor chip 600. According to embodiments, in a vertical direction (Z direction), the plurality of dummy structures 400 may be arranged between the second semiconductor chip 500 and the heat dissipation structure 100 and between the third semiconductor chip 600 and the heat dissipation structure 100. The plurality of dummy structures 400 may be arranged at a same vertical level as the bridge structure 200 and the first semiconductor chip 300 to prevent warpage of the semiconductor package 10a, and may provide a heat dissipation path of heat generated from the first semiconductor chip 300, the second semiconductor chip 500, and the third semiconductor chip 600 to induce thermal dispersion of the semiconductor package 10a. In FIGS. 1A and 1B, the semiconductor package 10a may include the two dummy structures 400 surrounding the bridge structure 200 and the first semiconductor chip 300. However, embodiments of the present disclosure are not limited thereto. For example, the semiconductor package 10 may include one of the dummy structures 400 or at least three dummy structures 400, and the one or more dummy structures 400 may be arranged between the bridge structure 200 and the first semiconductor chip 300. Herein, the term “vertical level” refers to a height according to a vertical direction (Z direction or-Z direction) from a first surface 110a of the heat dissipation structure 100.

In some embodiments, the first semiconductor chip 300, the second semiconductor chip 500, and the third semiconductor chip 600 may each independently be a logic chip or a memory chip. The logic chip may be a microprocessor. For example, the logic chip may be a microprocessor, such as a central processing unit (CPU), a graphics processing unit (GPU), or an application processor (AP), an analog element, or a digital signal processor.

The memory chip may be a volatile memory chip such as dynamic random access memory (DRAM) or static random access memory (SRAM), or a non-volatile memory chip such as phase-change random access memory (PRAM), magnetoresistive random access memory (MRAM), ferroelectric random access memory (FeRAM), or resistive random access memory (RRAM). In embodiments, the memory chip may be a high bandwidth memory (HBM) DRAM semiconductor chip.

In some embodiments, the first semiconductor chip 300 may be a memory chip, and the second semiconductor chip 500 and the third semiconductor chip 600 may each be a logic chip. However, embodiments of the present disclosure are not limited thereto.

In embodiments, the bridge structure 200, the first semiconductor chip 300, and the plurality of dummy structures 400 may be horizontally surrounded by a first gap-fill insulating layer 120. For example, a side surface of the bridge structure 200, a side surface of the first semiconductor chip 300, and a side surface of each of the plurality of dummy structures 400 may be covered by the first gap-fill insulating layer 120. According to embodiments, the second semiconductor chip 500 and the third semiconductor chip 600 may be horizontally surrounded by a second gap-fill insulating layer 130. For example, a side surface of the second semiconductor chip 500 and a side surface of the third semiconductor chip 600 may be covered by the second gap-fill insulating layer 130.

The first gap-fill insulating layer 120 and the second gap-fill insulating layer 130 may fill an empty space within the semiconductor package 10a to improve structural stability of the semiconductor package 10a. In some embodiments, the first gap-fill insulating layer 120 and the second gap-fill insulating layer 130 may be configured in different layers. In some embodiments, the first gap-fill insulating layer 120 and the second gap-fill insulating layer 130 may be integrally provided as a single body.

In some embodiments, each of the first gap-fill insulating layer 120 and the second gap-fill insulating layer 130 may include an oxide and/or a nitride. For example, each of the first gap-fill insulating layer 120 and the second gap-fill insulating layer 130 may include silicon oxide and/or silicon nitride.

In embodiments, the second semiconductor chip 500 may include a semiconductor substrate 510 including a semiconductor element layer 520, and a plurality of penetrating electrodes 514 passing through the semiconductor substrate 510 in a vertical direction (Z direction). According to embodiments, the plurality of penetrating electrodes 514 may be electrically connected to an individual element included in the semiconductor element layer 520.

In some embodiments, the semiconductor substrate 510 may be formed from a semiconductor wafer. The semiconductor substrate 510 may include, for example, silicon (Si). Alternatively, the semiconductor substrate 510 may include a semiconductor element such as germanium (Ge), or a compound semiconductor such as silicon carbide (SiC), gallium arsenide (GaAs), indium arsenide (InAs), and indium phosphide (InP). The semiconductor substrate 510 may include a conductive area, for example, the semiconductor element layer 520 on which a well doped with impurities or a structure doped with impurities is formed. The semiconductor element layer 520 may have various element isolation structure such as a shallow trench isolation (STI) structure. The terms “SiC,” “GaAs,” “InAs,” and “InP” used herein refer to materials composed of elements included in each of the terms, and is not chemical formulas that represent a stoichiometric relationship, and terms described below may be understood similarly.

In some embodiments, the plurality of penetrating electrodes 514 may include a conductive plug passing through the semiconductor substrate 510 in the vertical direction (Z direction), and a conductive barrier layer disposed on an external surface of the conductive plug. The conductive plug may include at least one material selected from among copper (Cu), nickel (Ni), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), and ruthenium (Ru). The conductive barrier layer may include at least one material selected from among Ti, titanium nitride (TiN), Ta, tantalum nitride (TaN), W, tungsten nitride (WN), Ru, and Co.

The semiconductor substrate 510 may include an active surface on which the semiconductor element layer 520 is formed, and an inactive surface opposite to the active surface. The second semiconductor chip 500 may include a metal wiring structure 540 disposed on the active surface of the semiconductor substrate 510, and a wiring insulating layer 530 surrounding the metal wiring structure 540. For example, an upper surface of the wiring insulating layer 530 may be in contact with the active surface of the semiconductor substrate 510.

For example, the metal wiring structure 540 may include a back end of line (BEOL) structure on the active surface. The metal wiring structure 540 may include a plurality of wiring lines 542 and a plurality of wiring vias 544. The plurality of wiring lines 542 may each extend in a horizontal direction (e.g., an X direction and/or a Y direction) within the wiring insulating layer 530. The plurality of wiring lines 542 may be located at different levels in the vertical direction (e.g., the Z direction) within the wiring insulating layer 530 and may form a multi-layer wiring structure. The plurality of wiring vias 544 may extend in the vertical direction (Z direction) between the plurality of wiring lines located at different vertical levels, and electrically connect the plurality of wiring lines 542 located at the different levels. The metal wiring structure 540 may be in contact with lower surfaces of the plurality of penetrating electrodes 514 and electrically connected to the plurality of penetrating electrodes 514. In addition, the metal wiring structure 540 may be electrically connected to an individual element included in the semiconductor element layer 520.

In some embodiments, the plurality of wiring lines 542 and the plurality of wiring vias 544 may include a metal such as Cu, Al, W, Ti, Ta, In, Mo, Mn, Co, Sn, Ni, Mg, Re, Be, Ga, and Ru, and any alloy thereof.

In some embodiments, the wiring insulating layer 530 may include an oxide and/or a nitride. For example, the wiring insulating layer 530 may include silicon oxide and/or silicon nitride. In some embodiments, the wiring insulating layer 530 may include tetraethyl orthosilicate (TEOS), phosphor silicate glass (PSG), boro-phosphor silicate glass (BPSG), undoped silicate glass (USG), plasma enhanced-TEOS (PE-TEOS), high density plasma-chemical vapor deposition (HDP-CVD), or any combinations thereof. In some embodiments, the wiring insulating layer 530 may have a single-layered or multi-layered structure.

The second semiconductor chip 500 may include a first passivation layer 550 covering the inactive surface of the semiconductor substrate 510, and a plurality of first conductive vias 552 passing through the first passivation layer 550 in the vertical direction (Z direction), and may include a second passivation layer 560 covering a bottom surface of the wiring insulating layer 530, and a plurality of second conductive vias 562 passing through the second passivation layer 560 in the vertical direction (Z direction). In embodiments, the metal wiring structure 540 may be in contact with the plurality of penetrating electrodes 514 and the plurality of second conductive vias 562.

According to embodiments, the plurality of first conductive vias 552 may be spaced apart from each other in a horizontal direction (X direction and/or Y direction) and electrically insulated from each other by the first passivation layer 550. For example, side surfaces of the plurality of first conductive vias 552 may be covered by the first passivation layer 550. According to embodiments, the plurality of first conductive vias 552 may be arranged on the plurality of penetrating electrodes 514 and may be in contact with an upper surface of each of the plurality of penetrating electrodes 514. According to embodiments, upper surfaces of the plurality of first conductive vias 552 and an upper surface of the first passivation layer 550 may be arranged on the same plane and may constitute a first surface 500a of the second semiconductor chip 500. For example, the first surface 500a of the second semiconductor chip 500 may face the heat dissipation structure 100.

According to embodiments, the plurality of second conductive vias 562 may be apart from each other in the horizontal direction (X direction and/or Y direction) and electrically insulated from each other by the second passivation layer 560. For example, side surfaces of the plurality of second conductive vias 562 may be covered by the second passivation layer 560. According to embodiments, upper surfaces of the plurality of second conductive vias 562 may be in contact with the metal wiring structure 540. According to embodiments, bottom surfaces of the plurality of second conductive vias 562 and a bottom surface of the second passivation layer 560 may be arranged on the same plane and may constitute a second surface 500b that is opposite to the first surface 500a of the second semiconductor chip 500.

For example, the active surface of the semiconductor substrate 510 may face in a same direction as a facing direction of the second surface 500b of the second semiconductor chip 500, and the inactive surface of the semiconductor substrate 510 may face in a same direction as a facing direction of the first surface 500a of the second semiconductor chip 500.

In some embodiments, the first passivation layer 550 and the second passivation layer 560 may each include an oxide and/or a nitride. For example, each of the first passivation layer 550 and the second passivation layer 560 may include at least one material from among silicon oxide (SiO), silicon nitride (SiN), silicon carbon nitrate (SiCN), silicon carbonate (SiCO), and polymer resin containing oxygen/nitrogen. For example, the polymer material may include polyimide (PI), polybenzoxazole (PBO), and epoxy.

In some embodiments, each of the plurality of first conductive vias 552 and the plurality of second conductive vias 562 may include at least one material selected from among Cu, Ni, Au, Ag, W, Ti, Ta, In, Mo, Mn, Co, Sn, Mg, Re, Be, Ga, and Ru. According to embodiments, each of the plurality of first conductive vias 552 and the plurality of second conductive vias 562 may include a seed layer, and the conductive seed layer may include chrome (Cr), W, Ti, Cu, NI, Al, palladium (Pd), Au, or any combinations thereof.

According to embodiments, the third semiconductor chip 600 may have a structure similar to a structure of the second semiconductor chip 500.

For example, the third semiconductor chip 600 may include a semiconductor substrate 610 including a semiconductor element layer 620, and a plurality of penetrating electrodes 614 passing through the semiconductor substrate 610 in the vertical direction (Z direction). The semiconductor substrate 610 may include an active surface and an inactive surface opposite to the active surface. The third semiconductor chip 600 may include a metal wiring structure 640 disposed on the active surface of the semiconductor substrate 610, and a wiring insulating layer 630 surrounding the metal wiring structure 640. For example, the metal wiring structure 640 may include a plurality of wiring lines 642 and a plurality of wiring vias 644.

For example, the third semiconductor chip 600 may include a first passivation layer 650 covering the inactive surface of the semiconductor substrate 610, and a plurality of first conductive vias 652 passing through the first passivation layer 650 in a vertical direction (Z direction), and may include a second passivation layer 660 covering a bottom surface of the wiring insulating layer 630, and a plurality of second conductive vias 662 passing through the second passivation layer 660 in the vertical direction (Z direction). According to embodiments, the metal wiring structure 640 may be in contact with the plurality of penetrating electrodes 614 and the plurality of second conductive vias 662.

For example, upper surfaces of the plurality of first conductive vias 652 and an upper surface of the first passivation layer 650 may constitute a first surface 600a of the third semiconductor chip 600, and bottom surfaces of the plurality of second conductive vias 662 and a bottom surface of the second passivation layer 660 may constitute a second surface 600b of the third semiconductor chip 600. For example, the active surface of the semiconductor substrate 610 may face in a same direction as a facing direction of the second surface 600b of the third semiconductor chip 600, and the inactive surface of the semiconductor substrate 610 may face in a same direction as a facing direction of the first surface 600a of the third semiconductor chip 600.

Elements of the third semiconductor chip 600 may respectively include the same materials as the elements of the second semiconductor chip 500 having the same name as described above, or a material similar thereto.

According to embodiments, the second semiconductor chip 500 and the third semiconductor chip 600 may be arranged apart from each other at a same vertical level. According to embodiments, the first gap-fill insulating layer 120 may include a portion arranged between the second semiconductor chip 500 and the third semiconductor chip 600. According to embodiments, the first surface 500a of the second semiconductor chip 500 and the first surface 600a of the third semiconductor chip 600 may be coplanar, and the second surface 500b of the second semiconductor chip 500 and the second surface 600b of the third semiconductor chip 600 may be coplanar.

According to embodiments, the bridge structure 200 may overlap the second semiconductor chip 500 and the third semiconductor chip 600 in the vertical direction (Z direction). For example, the bridge structure 200 may vertically overlap at least a portion of the second semiconductor chip 500 and, independently, may vertically overlap at least a portion of the third semiconductor chip 600.

According to embodiments, the bridge structure 200 may include a bridge wiring structure 220, an insulating substrate 210 surrounding the bridge wiring structure 220, a bridge-side bonding dielectric layer 212 covering an upper surface of the insulating substrate 210, a bridge-side passivation layer 230 covering a bottom surface of the insulating substrate 210, and a plurality of bridge-side conductive vias 232 which pass through the bridge-side passivation layer 230 in the vertical direction (Z direction) to be in contact with the bridge wiring structure 220. The bridge structure 200 may include a first surface 200a facing the heat dissipation structure 100, and a second surface 200b opposite to the first surface 200a and facing the second semiconductor chip 500 and the third semiconductor chip 600.

According to embodiments, the plurality of bridge-side conductive vias 232 may be apart from each other in a horizontal direction (X direction and/or Y direction), with the bridge-side passivation layer 230 therebetween. According to embodiments, an upper surface of each of the plurality of bridge-side conductive vias 232 may be in contact with the bridge wiring structure 220.

According to embodiments, an upper surface of the bridge-side bonding dielectric layer 212 may constitute the first surface 200a of the bridge structure 200. According to embodiments, bottom surfaces of the plurality of bridge-side conductive vias 232 and a bottom surface of the bridge-side passivation layer 230 may constitute the second surface 200b of the bridge structure 200.

In some embodiments, the insulating substrate 210 may include a single-layered or multi-layered insulating film. In some embodiments, the insulating substrate 210 may include any one selected from among photo imageable dielectric (PID), an Ajinomoto build-up film (ABF), solder resist (SR), an epoxy molding compound (EMC), FR-4, and bismaleimide triazine (BT).

In some embodiments, the bridge-side bonding dielectric layer 212 may include an oxide and/or a nitride. For example, the bridge-side bonding dielectric layer 212 may include silicon oxide and/or silicon nitride.

According to embodiments, the bridge wiring structure 220 may include a plurality of wiring lines 222 and a plurality of wiring vias 224. The plurality of wiring lines 222 may extend in a horizontal direction (e.g., the X direction and/or the Y direction) within the insulating substrate 210. The plurality of wiring lines 222 may be located at different levels in a vertical direction (e.g., the Z direction) within the insulating substrate 210 and may form a multi-layered wiring structure. The plurality of wiring vias 224 may extend in the vertical direction (Z direction) between the plurality of wiring lines 222 located at different vertical levels and electrically connect the plurality of wiring lines 222 located at different vertical levels. The bridge wiring structure 220 may be in contact with upper surfaces of the plurality of bridge-side conductive vias 232.

In some embodiments, the plurality of wiring lines 222 and the plurality of wiring vias 224 may include a metal, such as Cu, Al, W, Ti, Ta, In, Mo, Mn, Co, Sn, Ni, Mg, Re, Be, Ga, and Ru, and any alloys thereof.

In some embodiments, the bridge-side passivation layer 230 may include an oxide and/or a nitride. For example, the bridge-side passivation layer 230 may include at least one material from among SiO, SiN, SiCN, SiCO, and polymer material containing oxygen/nitrogen. For example, the polymer material may include PI, PBO, and epoxy.

In some embodiments, the plurality of bridge-side conductive vias 232 may include at least one material selected from among Cu, Ni, Au, Ag, W, Ti, Ta, In, Mo, Mn, Co, Sn, Mg, Re, Be, Ga, and Ru. According to embodiments, the plurality of bridge-side conductive vias 232 may include a seed layer, and the conductive seed layer may include Cr, W, Ti, Cu, Ni, Al, Pd, Au, or any combinations thereof.

According to embodiments, the bridge structure 200 may be bonded to the second semiconductor chip 500 and the third semiconductor chip 600. For example, the second surface 200b of the bridge structure 200 may be in contact with the first surface 500a of the second semiconductor chip 500 and the first surface 600a of the third semiconductor chip 600.

In some embodiments, the bridge structure 200 and the second semiconductor chip 500 may be bonded together through dielectric-to-dielectric bonding and metal-to-metal bonding. The bottom surface of the bridge-side passivation layer 230 of the bridge structure 200 may be in contact with the upper surface of the first passivation layer 550 of the second semiconductor chip 500, and a bottom surface of a first group from among the plurality of bridge-side conductive vias 232 of the bridge structure 200 may be in contact with the upper surface of the plurality of first conductive vias 552 of the second semiconductor chip 500. For example, the first group from among the plurality of bridge-side conductive vias 232 of the bridge structure 200 may be aligned in the vertical direction (Z direction) with the plurality of first conductive vias 552 of the second semiconductor chip 500. In the vertical direction (Z direction), after contacting dielectrics with dielectrics and metals with metals, pressure and heat may be applied to diffuse metal atoms and dielectric materials at an interface, so that dielectric-to-dielectric bonding and metal-to-metal bonding may be formed. For example, the bridge-side passivation layer 230 of the bridge structure 200 may form dielectric-to-dielectric bonding with the first passivation layer 550 of the second semiconductor chip 500, and the first group from among the plurality of bridge-side conductive vias 232 of the bridge structure 200 of the bridge structure 200 may form metal-to-metal bonding with the plurality of first conductive vias 552 of the second semiconductor chip 500. Bonding between the bridge structure 200 and the second semiconductor chip 500 may be formed through a combination of dielectric-to-dielectric bonding and metal-to-metal bonding. For example, the bridge structure 200 and the second semiconductor chip 500 may be bonded together through metal-to-metal bonding between the bridge-side conductive vias 232 and the plurality of first conductive vias 552 and dielectric-to-dielectric bonding between the bridge-side passivation layer 230, which is formed therearound, and the first passivation layer 550 of the second semiconductor chip 500.

Herein, “dielectric-to-dielectric bonding” may be understood as a concept including oxide-oxide bonding, nitride-nitride-bonding, and oxide-nitride bonding, and “metal-to-metal bonding” may be understood as a concept including copper-copper bonding.

In some embodiments, similar to the second semiconductor chip 500, the bridge structure 200 and the third semiconductor chip 600 may be bonded together through dielectric-to-dielectric bonding and metal-to-metal bonding. The bottom surface of the bridge-side passivation layer 230 of the bridge structure 200 may be in contact with the upper surface of the first passivation layer 650 of the third semiconductor chip 600, and a bottom surface of a second group from among the plurality of bridge-side conductive vias 232 of the bridge structure 200 may be in contact with the upper surface of a first group from among the plurality of first conductive vias 652 of the third semiconductor chip 600 (meanwhile, a second group from among the plurality of first conductive vias 652 of the third semiconductor chip 600 may form bonding with a plurality of conductive vias 332 of the third semiconductor chip 600 to be described below). For example, the second group from among the bridge-side conductive vias 232 of the bridge structure 200 may be aligned in the vertical direction (Z direction) with the first group from among the plurality of first conductive vias 652 of the third semiconductor chip 600.

Bonding between the bridge structure 200 and the third semiconductor chip 600 may be formed through a combination of dielectric-to-dielectric bonding and metal-to-metal bonding. For example, the bridge structure 200 and the third semiconductor chip 600 may be bonded together through metal-to-metal bonding between the bridge-side conductive vias 232 and the plurality of first conductive vias 652 and dielectric-to-dielectric bonding between the bridge-side passivation layer 230, which is formed therearound, and the first passivation layer 650 of the third semiconductor chip 600.

For example, the bridge-side passivation layer 230 of the bridge structure 200 may form dielectric-to-dielectric bonding with the first passivation layer 650 of the third semiconductor chip 600, and the second group from among the plurality of bridge-side conductive vias 232 of the bridge structure 200 may form metal-to-metal bonding with the first group from among the plurality of first conductive vias 652 of the third semiconductor chip 600. Meanwhile, the second group from among the plurality of first conductive vias 652 of the third semiconductor chip 600 may form bonding with the plurality of conductive vias 332 of the third semiconductor chip 600 to be described below.

For example, a first portion of the bridge-side passivation layer 230 vertically overlapping the second semiconductor chip 500 may be bonded to the first passivation layer 550 of the second semiconductor chip 500, and a second portion of the bridge-side passivation layer 230 vertically overlapping the third semiconductor chip 600 may be bonded to the first passivation layer 650 of the third semiconductor chip 600. For example, the first group from among the plurality of bridge-side conductive vias 232 may be bonded on the second semiconductor chip 500 with the plurality of first conductive vias 552 of the second semiconductor chip 500, and the second group from among the plurality of bridge-side conductive vias 232 may be bonded on the third semiconductor chip 600 to the first group from among the plurality of first conductive vias 652 of the third semiconductor chip 600.

According to embodiments, the second semiconductor chip 500 and the third semiconductor chip 600 may be electrically connected to each other through the bridge structure 200.

According to embodiments, the bridge-side passivation layer 230 may include a same material as a material of the first passivation layer 550 of the second semiconductor chip 500. In some embodiments, the bridge-side passivation layer 230 may include a material different from a material of the first passivation layer 550 of the second semiconductor chip 500.

In some embodiments, the bridge-side passivation layer 230 may include a same material as a material of the first passivation layer 650 of the third semiconductor chip 600. In some embodiments, the bridge-side passivation layer 230 may include a material different from a material of the first passivation layer 650 of the third semiconductor chip 600.

In some embodiments, the first group from among the plurality of bridge-side conductive vias 232 may include a same material as the plurality of first conductive vias 552 of the second semiconductor chip 500. In some embodiments, the first group from among the plurality of bridge-side conductive vias 232 of may include a material different from a material of the plurality of first conductive vias 552 of the second semiconductor chip 500.

In some embodiments, the second group from among the plurality of bridge-side conductive vias 232 of p may include a same material as a material of the first group from among the plurality of first conductive vias 652 of the third semiconductor chip 600. In some embodiments, the second group from among the plurality of bridge-side conductive vias 232 may include a material different from a material of the first group from among the first conductive vias 652 of the third semiconductor chip 600.

In some embodiments, the first semiconductor chip 300 may be arranged apart from the bridge structure 200 in a horizontal direction. According to embodiments, the first gap-fill insulating layer 120 may be between the bridge structure 200 and the first semiconductor chip 300.

According to embodiments, the first semiconductor chip 300 may include a semiconductor substrate 310 including a semiconductor element layer 320, a passivation layer 330 disposed on an active surface on the side of the semiconductor element layer 320 of the semiconductor substrate 310, a bonding dielectric layer 312 on an inactive surface opposite to the active surface of the semiconductor substrate 310, and a plurality of conductive vias 332 passing through the passivation layer 330 in a vertical direction (Z direction). The first semiconductor chip 300 may include a first surface 300a facing the heat dissipation structure 100, and a second surface 300b opposite to the first surface 300a and facing the third semiconductor chip 600.

According to embodiments, the plurality of conductive vias 332 may be apart from each other in a horizontal direction (X direction and/or Y direction) and may be apart and insulated from each other with the passivation layer 330 therebetween. The plurality of conductive vias 332 may be electrically connected to individual elements of the semiconductor element layer 320.

In some embodiments, the passivation layer 330 may include an oxide and/or a nitride. For example, the passivation layer 330 may include at least one material from among SiO, SIN, SiCN, SiCO, and a polymer material containing oxygen/nitrogen. For example, the polymer material may include PI, PBO, and epoxy.

In some embodiments, the bonding dielectric layer 312 may include an oxide and/or a nitride. For example, the bonding dielectric layer 312 may include silicon oxide and/or silicon nitride.

According to embodiments, an upper surface of the bonding dielectric layer 312 may constitute the first surface 300a of the first semiconductor chip 300. According to embodiments, a bottom surface of the plurality of conductive vias 332 and a bottom surface of the passivation layer 330 may constitute the second surface 300b of the first semiconductor chip 300.

According to embodiments, the second surface 300b of the first semiconductor chip 300 may be in contact with the first surface 600a of the third semiconductor chip 600, and the first semiconductor chip 300 and the third semiconductor chip 600 may be bonded together.

In some embodiments, the first semiconductor chip 300 and the third semiconductor chip 600 may be formed through dielectric-to-dielectric bonding or metal-to-metal bonding. The bottom surface of the passivation layer 330 of the first semiconductor chip 300 may be in contact with the upper surface of the first passivation layer 650 of the third semiconductor chip 600, and the bottom surfaces of the plurality of conductive vias 332 of the first semiconductor chip 300 may be in contact with the upper surface of the second group from among the plurality of first conductive vias 652 of the third semiconductor chip 600 (as described above, the first group from among the plurality of first conductive vias 652 of the third semiconductor chip 600 is in contact with the bridge structure 200). For example, the conductive vias 332 of the first semiconductor chip 300 may be respectively aligned in a vertical direction (Z direction) with the second group from among the plurality of first conductive vias 652 of the third semiconductor chip 600. For example, the passivation layer 330 of the first semiconductor chip 300 may form dielectric-to-dielectric bonding with the first passivation layer 650 of the third semiconductor chip 600, and the plurality of conductive vias 332 of the first semiconductor chip 300 may form metal-to-metal bonding with the second group from among the plurality of first conductive vias 652 of the third semiconductor chip 600.

For example, a first portion of the first passivation layer 650 of the third semiconductor chip 600 that vertically overlaps the bridge structure 200 may be bonded to the second portion of the bridge-side passivation layer 230 vertically overlapping the third semiconductor chip 600. A second portion of the first passivation layer 650 of the third semiconductor chip 600 that vertically overlaps the first semiconductor chip 300 may be bonded to the passivation layer 330 of the first semiconductor chip 300. For example, the first group from among the plurality of first conductive vias 652 of the third semiconductor chip 600, that is vertically overlapping with the bridge structure 200, may be bonded to some of the plurality of bridge-side conductive vias 232, and the second group from among the plurality of first conductive vias 652 of the third semiconductor chip 600, that vertically overlaps with the first semiconductor chip 300, may be bonded to the plurality of conductive vias 332 of the first semiconductor chip 300.

According to embodiments, the first semiconductor chip 300 and the third semiconductor chip 600 may be directly bonded and electrically connected to each other.

In some embodiments, the passivation layer 330 of the first semiconductor chip 300 may include a same material as a material of the first passivation layer 650 of the third semiconductor chip 600. In some embodiments, the passivation layer 330 of the first semiconductor chip 300 may include a material different from a material of the first passivation layer 650 of the third semiconductor chip 600.

In some embodiments, the plurality of conductive vias 332 of the first semiconductor chip 300 may include a same material as a material of the second group from among the plurality of first conductive vias 652 of the third semiconductor chip 600. In some embodiments, the plurality of conductive vias 332 of the first semiconductor chip 300 may include a material different from a material of the second group from among the plurality of first conductive vias 652 of the third semiconductor chip 600.

According to embodiments, the plurality of dummy structures 400 may be arranged to be apart from the bridge structure 200 and the first semiconductor chip 300, around the bridge structure 200 and the first semiconductor chip 300. The first gap-fill insulating layer 120 may be between the plurality of dummy structures 400 and the bridge structure 200 and between the plurality of dummy structures 400 and the first semiconductor chip 300.

In some embodiments, the plurality of dummy structures 400 may have different planar areas. In some embodiments, the plurality of dummy structures 400 may have a same planar area as each other, unlike shown in FIGS. 1A and 1B.

According to embodiments, the plurality of dummy structures 400 may include a dummy substrate 410 and a dummy-side bonding dielectric layer 412 on the dummy substrate 410. For example, the plurality of dummy structures 400 may each include a first surface 400a facing the heat dissipation structure 100, and a second surface 400b opposite to the first surface 400a. In some embodiments, an upper surface of the dummy-side bonding dielectric layer 412 may constitute the first surface 400a of each of the dummy structures 400, and a bottom surface of the dummy substrate 410 may constitute the second surface 400b of each of the dummy structures 400.

In FIG. 1A, in a plan view, each of the plurality of dummy structures 400 is arranged within a boundary of at least one from among the second semiconductor chip 500 and the third semiconductor chip 600. However, embodiments of the present disclosure are not limited thereto. For example, the plurality of dummy structures 400 may each include a portion not overlapping the second semiconductor chip 500 and the third semiconductor chip 600 in the vertical direction (Z direction).

In FIG. 1B, the bottom surface of the dummy substrate 410 of each of the plurality of dummy structures 400 is in direct contact with the upper surface of the first passivation layer 550 of the second semiconductor chip 500 and the upper surface of the first passivation layer 650 of the third semiconductor chip 600. However, embodiments of the present disclosure are not limited thereto. For example, the plurality of dummy structures 400 may each further include a bonding dielectric layer on the bottom surface of the dummy substrate 410. In this case, the bonding dielectric layer on the bottom surface of the dummy substrate 410 may form dielectric-to-dielectric bonding with each of the first passivation layer 550 of the second semiconductor chip 500 and the first passivation layer 650 of the third semiconductor chip 600.

In some embodiments, the first gap-fill insulating layer 120 may be bonded through dielectric-to-dielectric bonding to the first passivation layer 550 of the second semiconductor chip 500 and the first passivation layer 650 of the third semiconductor chip 600. For example, bonding may be formed through diffusion of a dielectric material between the first gap-fill insulating layer 120 and the first passivation layer 550 of the second semiconductor chip 500, which are in contact with each other in the vertical direction (Z direction), and between the first gap-fill insulating layer 120 and the first passivation layer 650 of the third semiconductor chip 600.

According to embodiments, the second surface 400b of each of the plurality of dummy structures 400, the second surface 200b of the bridge structure 200, the second surface 300b of the first semiconductor chip 300, and the bottom surface of the first gap-fill insulating layer 120 may be coplanar. According to embodiments, the first surface 400a of each of the plurality of dummy structures 400, the first surface 200a of the bridge structure 200, the first surface 300a of the first semiconductor chip 300, and the upper surface of the first gap-fill insulating layer 120 may be coplanar.

According to embodiments, the heat dissipation structure 100 may be disposed on the plurality of dummy structures 400, the bridge structure 200, the first semiconductor chip 300, and the first gap-fill insulating layer 120. According to embodiments, the heat dissipation structure 100 may include a heat dissipation substrate 110 and a heat dissipation bonding dielectric layer 112 on a bottom surface of the heat dissipation substrate 110. According to embodiments, the heat dissipation structure 100 may include a second surface 100b opposite to the first surface 100a and facing the bridge structure 200.

In some embodiments, the heat dissipation substrate 110 may include a blank device wafer such as Si, soda lime glass, borosilicate glass, silicon carbide, silicon germanium, silicon nitride, gallium arsenide, sapphire, and various metals and ceramics. However, embodiments of the present disclosure are not limited to the examples described above.

In some embodiments, the heat dissipation bonding dielectric layer 112 may include an oxide and/or a nitride. For example, the heat dissipation bonding dielectric layer 112 may include silicon oxide and/or silicon nitride.

In some embodiments, a planar area of the heat dissipation structure 100 may be greater than a sum of a planar area of the second semiconductor chip 500 and a planar area of the third semiconductor chip 600. In some embodiments, the planar area of the heat dissipation structure 100 may be less than the sum of the planar area of the second semiconductor chip 500 and the planar area of the third semiconductor chip 600.

According to embodiments, the heat dissipation structure 100 may be bonded to the bridge structure 200, an upper surface of the first semiconductor chip 300, and upper surfaces of the plurality of dummy structures 400. For example, the second surface 100b of the heat dissipation structure 100 may be in contact with the first surface 400a of each of the plurality of dummy structures 400, the first surface 200a of the bridge structure 200, and the first surface 300a of the first semiconductor chip 300.

In some embodiments, the heat dissipation structure 100 may be bonded to the bridge structure 200, the first semiconductor chip 300, and the plurality of dummy structures 400 through dielectric-to-dielectric bonding. For example, a bottom surface of the heat dissipation bonding dielectric layer 112 of the heat dissipation structure 100 may be in contact with the upper surface of the bridge-side bonding dielectric layer 212 of the bridge structure 200 and the upper surface of the bonding dielectric layer 312 of the first semiconductor chip 300 and may form bonding by diffusing a dielectric material at an interface through heating and pressure.

In some embodiments, the heat dissipation bonding dielectric layer 112 of the heat dissipation structure 100 may include a same material as a material of the bridge-side bonding dielectric layer 212 of the bridge structure 200. In some embodiments, the heat dissipation bonding dielectric layer 112 of the heat dissipation structure 100 may include a material different from a material of the bridge-side bonding dielectric layer 212 of the bridge structure 200.

In some embodiments, the heat dissipation bonding dielectric layer 112 of the heat dissipation structure 100 may include a same material as a material of the bonding dielectric layer 312 of the first semiconductor chip 300. In some embodiments, the heat dissipation bonding dielectric layer 112 of the heat dissipation structure 100 may include a material different from a material of the bonding dielectric layer 312 of the first semiconductor chip 300.

In embodiments, the cover insulating layer 710 may cover the second surface 500b of the second semiconductor chip 500, the second surface 600b of the third semiconductor chip 600, and a bottom surface of the second gap-fill insulating layer 130.

According to embodiments, the semiconductor package may include a plurality of connection vias 712 passing through the cover insulating layer 710 in the vertical direction (Z direction), and a plurality of connection bumps 714 disposed on a bottom surface of the cover insulating layer 710 and respectively connected to the plurality of connection vias 712. The plurality of connection vias 712 may be respectively in contact with the plurality of second conductive vias 562 of the second semiconductor chip 500 and the plurality of second conductive vias 662 of the third semiconductor chip 600. According to embodiments, the plurality of connection vias 712 may be apart from each other in the horizontal direction (X direction and/or Y direction) and may be insulated from each other by the cover insulating layer 710.

In some embodiments, the cover insulating layer 710 may include one selected from among PID, ABF, SR, EMC, FR-4, and BT. However, embodiments of the present disclosure are not limited to the examples described above.

In some embodiments, the plurality of connection vias 712 may include Cu, Ni, Au, Ag, W, Ti, Ta, In, Mo, Mn, Co, Sn, Mg, Re, Be, Ga, Ru, Cr, W, Ti, Cu, Ni, Al, Pd, Au, or any alloys thereof.

In some embodiments, the plurality of connection bumps 714 may include Sn, Ag, CU, Ni, or any combinations thereof, but are not limited thereto. The plurality of connection bumps 714 may include a pillar structure, a ball structure, or a solder layer.

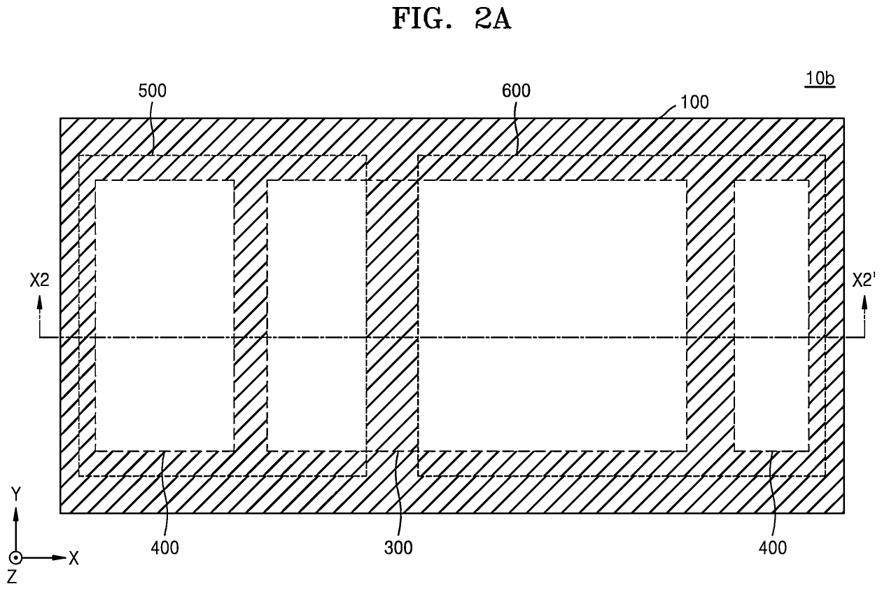

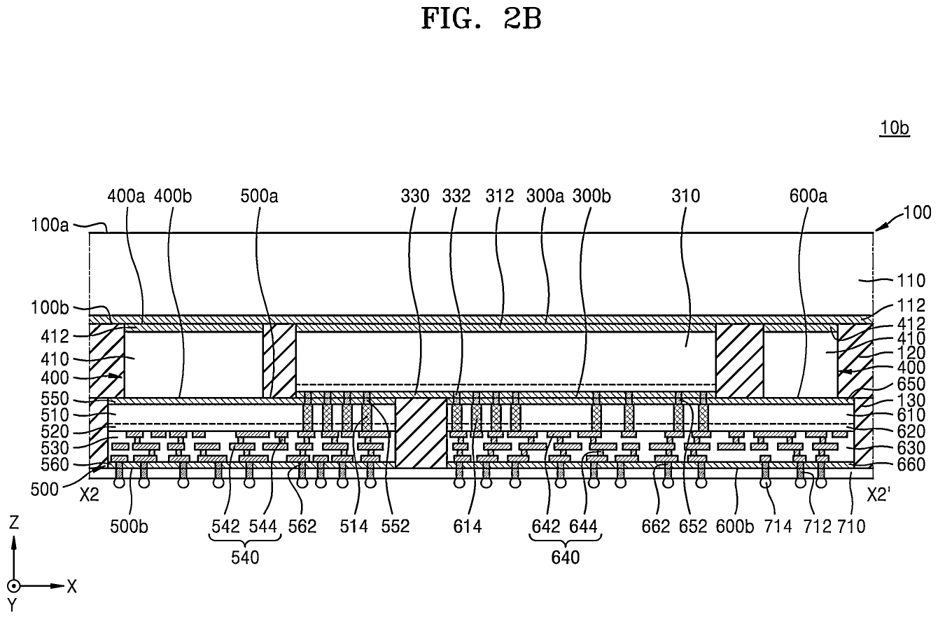

FIGS. 2A and 2B are diagrams for describing a semiconductor package 10b according to embodiments. FIG. 2A is a plan view of the semiconductor package 10b according to embodiments. FIG. 2B is a cross-sectional view taken along line X2-X2′ in FIG. 2A. A difference between the semiconductor package 10a and the semiconductor package 10b described with reference to FIGS. 1A and 1B is that the bridge structure 200 is omitted and whether the first semiconductor chip 300 vertically overlaps the second semiconductor chip 500 and the third semiconductor chip 600. In FIGS. 2A and 2B, the same reference characters as those of FIGS. 1A and 1B denote the same member, and repeated descriptions may be omitted.

Referring to FIGS. 2A and 2B, the first semiconductor chip 300 of the semiconductor package 10b may serve as the bridge structure 200 of the semiconductor package 10a described with reference to FIGS. 1A and 1B. According to embodiments, the first semiconductor chip 300 may overlap at least a portion of the second semiconductor chip 500 in the vertical direction (Z direction) and may overlap at least a portion of the third semiconductor chip 600 in the vertical direction (Z direction).

According to embodiments, the first semiconductor chip 300 may bonded to the second semiconductor chip 500 and the third semiconductor chip 600. For example, the second surface 300b of the first semiconductor chip 300 may be in contact with the first surface 500a of the second semiconductor chip 500 and the first surface 600a of the third semiconductor chip 600.

According to embodiments, the first semiconductor chip 300 may bonded to the second semiconductor chip 500 and the third semiconductor chip 600 through dielectric-to-dielectric bonding and metal-to-metal bonding. The bottom surface of the passivation layer 330 of the first semiconductor chip 300 may be in contact with the upper surface of the first passivation layer 550 of the second semiconductor chip 500 and the upper surface of the first passivation layer 650 of the third semiconductor chip 600. The plurality of conductive vias 332 of the first semiconductor chip 300 may be aligned and in contact with the plurality of first conductive vias 552 of the second semiconductor chip 500 and the plurality of first conductive vias 652 of the third semiconductor chip 600 in the vertical direction (Z direction). For example, the passivation layer 330 may form dielectric-to-dielectric bonding with the first passivation layer 550 of the second semiconductor chip 500 and the first passivation layer 650 of the third semiconductor chip 600. For example, a first group from among the plurality of conductive vias 332 of the first semiconductor chip 300 may form metal-to-metal bonding with the plurality of first conductive vias 552 of the second semiconductor chip 500, and the second group from among the plurality of conductive vias 332 of the first semiconductor chip 300 may form metal-to-metal bonding with the plurality of first conductive vias 652 of the third semiconductor chip 600.

According to embodiments, the first semiconductor chip 300 may not only be electrically connected to each of the second semiconductor chip 500 and the third semiconductor chip 600, but also mediate electrical connection between the second semiconductor chip 500 and the third semiconductor chip 600. Herein, the first semiconductor chip 300 of the semiconductor package 10b may be referred to as a bridge chip. In addition, herein, the semiconductor substrate 310 of the first semiconductor chip 300 may be referred to as a bridge substrate.

Hereinafter, a method of manufacturing a semiconductor package, according to embodiments, is described.

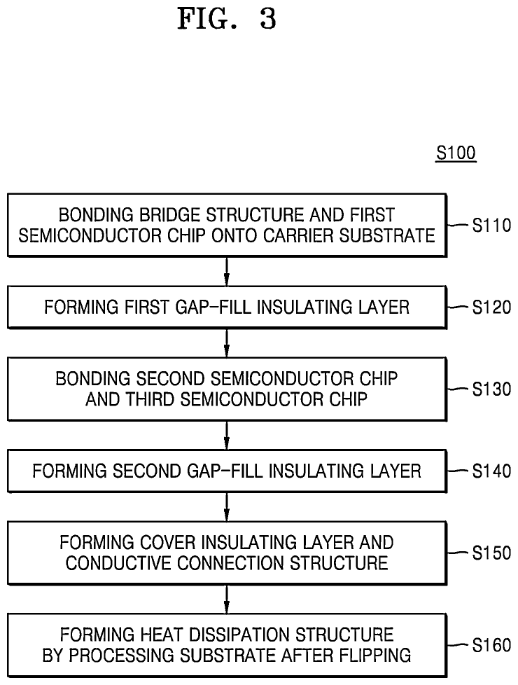

FIG. 3 is a flowchart of a method S100 of manufacturing a semiconductor package, according to embodiments.

Referring to FIG. 3, the method S100 of manufacturing the semiconductor package, according to embodiments, may include bonding a bridge structure and a first semiconductor chip onto a carrier structure (operation S110), forming a first gap-fill insulating layer (operation S120), bonding a second semiconductor chip and a third semiconductor chip onto the bridge structure, the first semiconductor chip, and the first gap-fill insulating layer (operation S130), forming a second gap-fill insulating layer (operation S140), forming a cover insulating layer and a conductive connection structure (operation S150), and flipping the previous result and forming a heat dissipation structure by processing the carrier substrate (operation S160).

When an embodiment may be implemented in another way, a process order may be performed differently from the described order. For example, two consecutively described processes may be performed substantially at the same time and may be performed in order that is opposite to the order described.

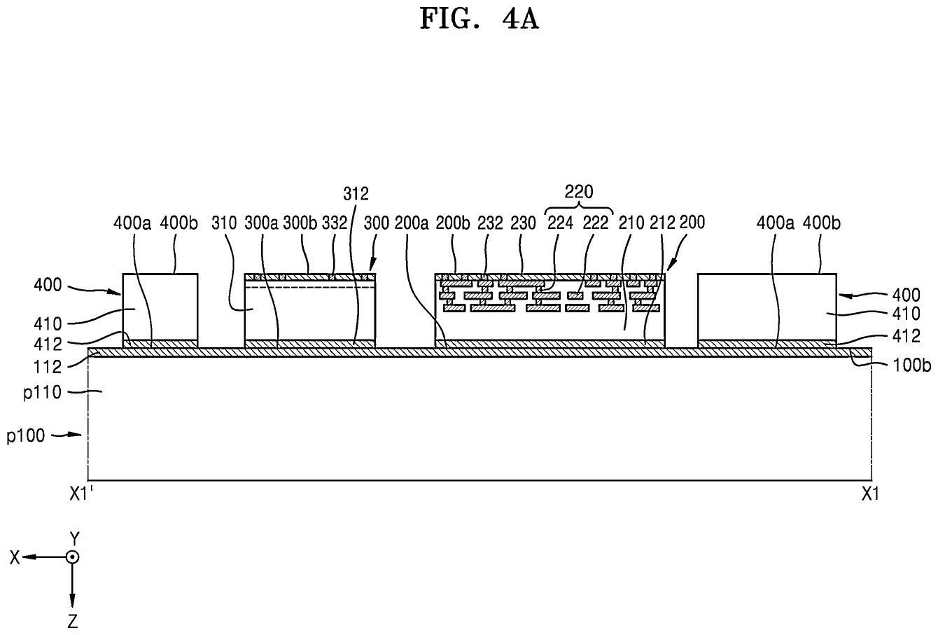

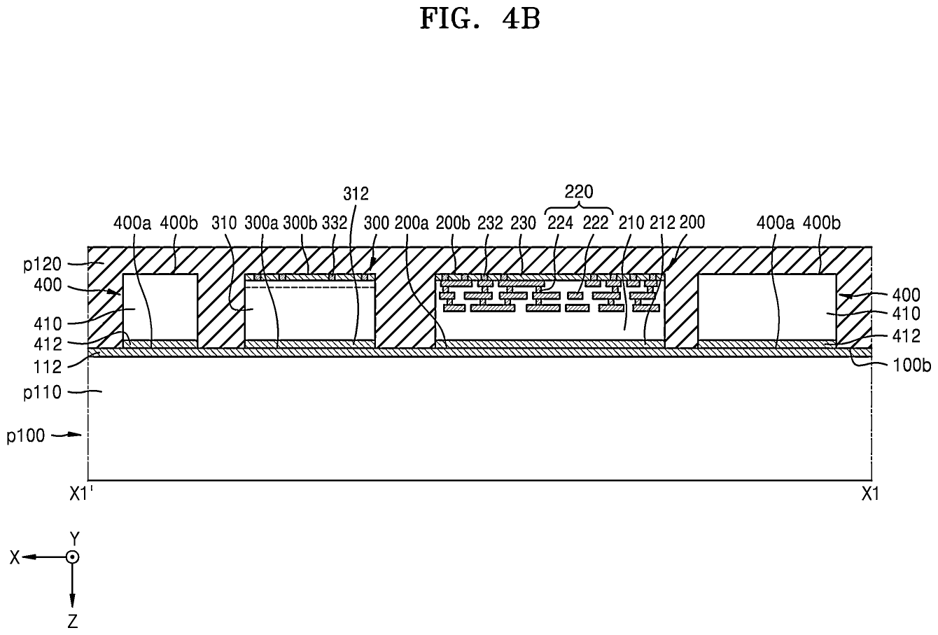

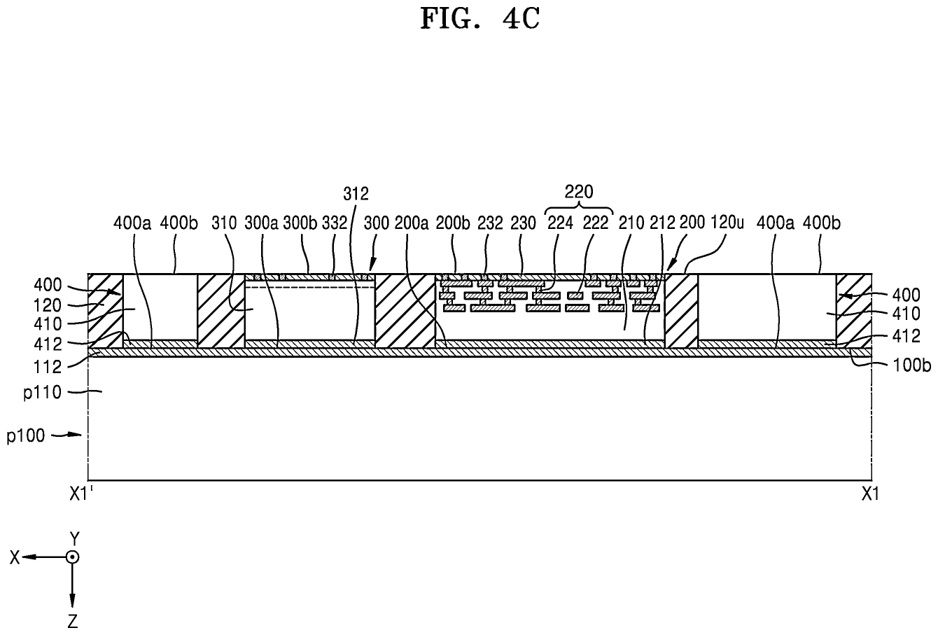

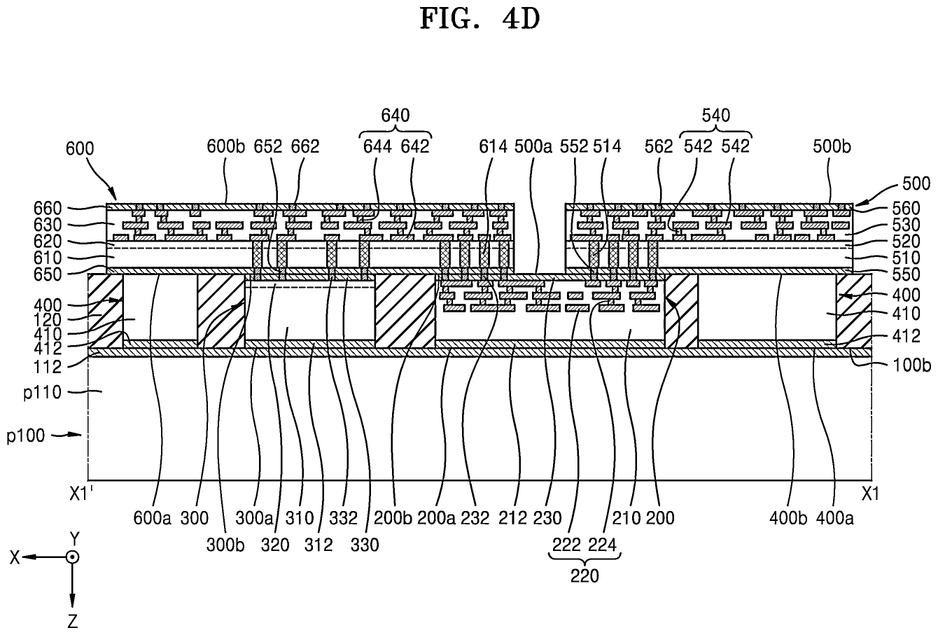

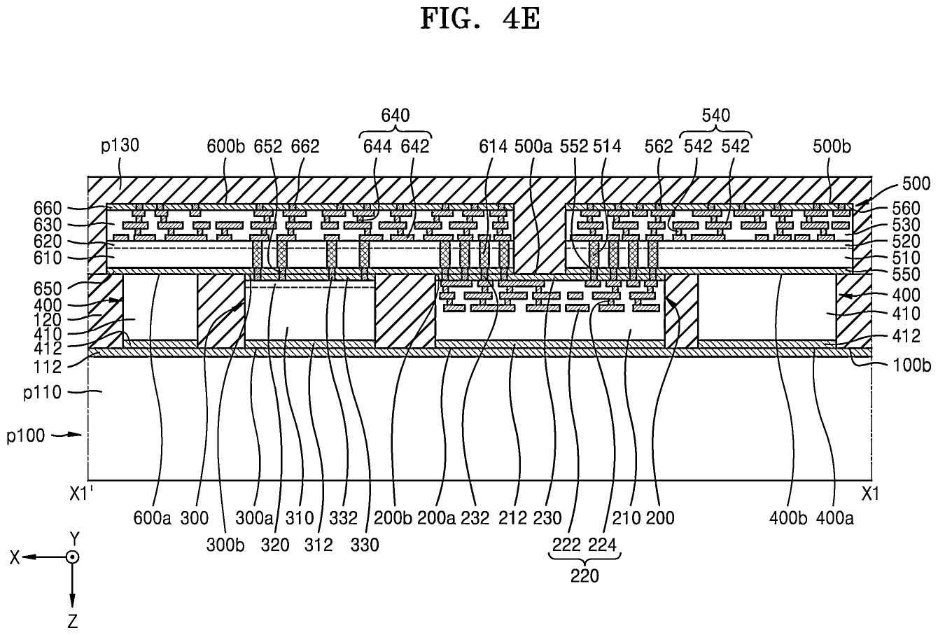

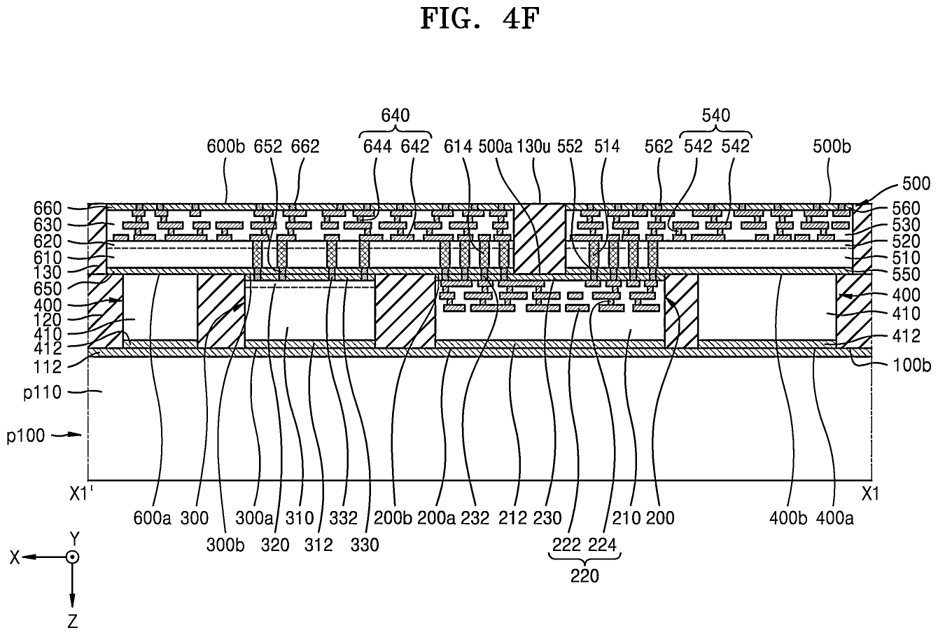

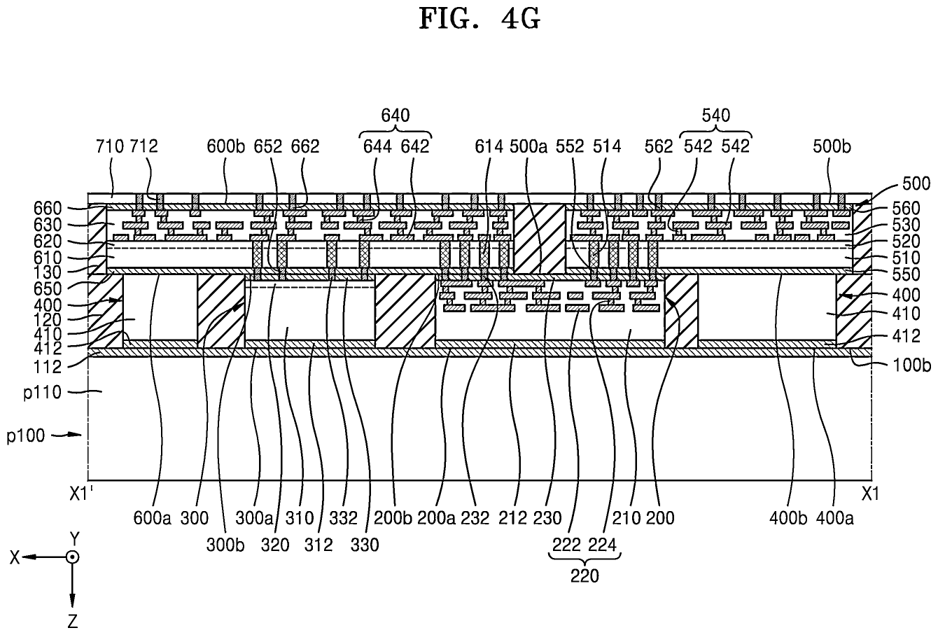

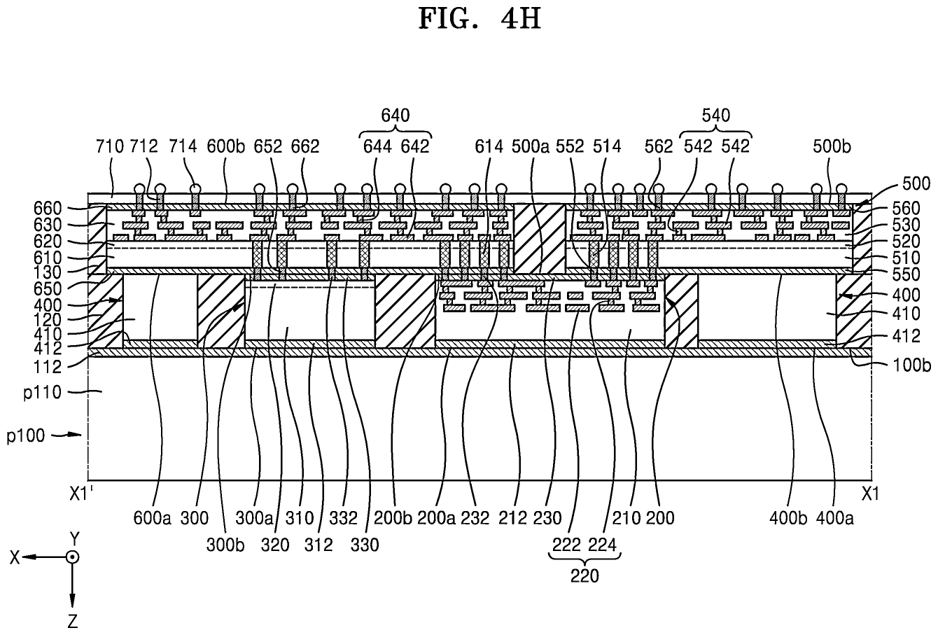

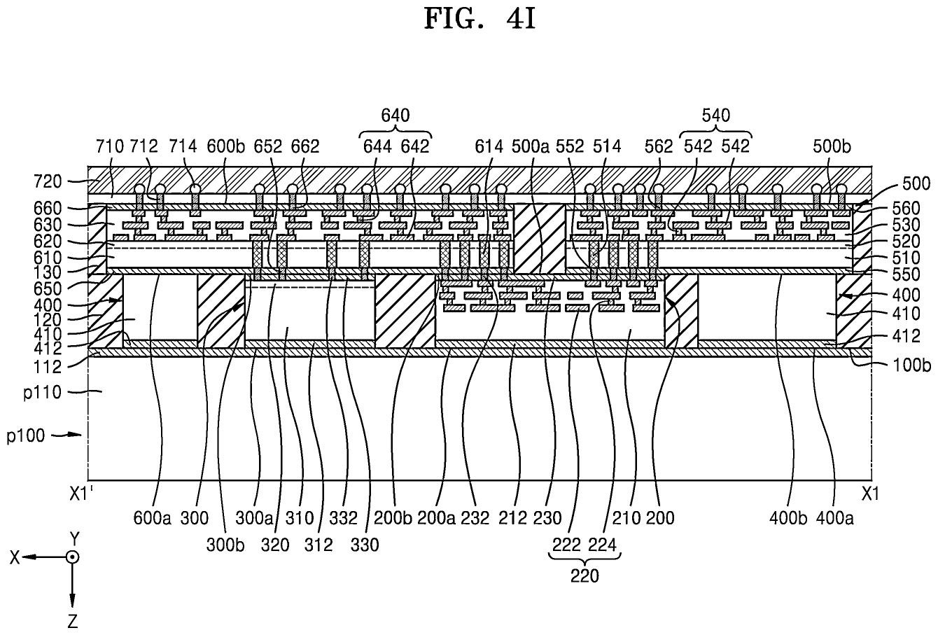

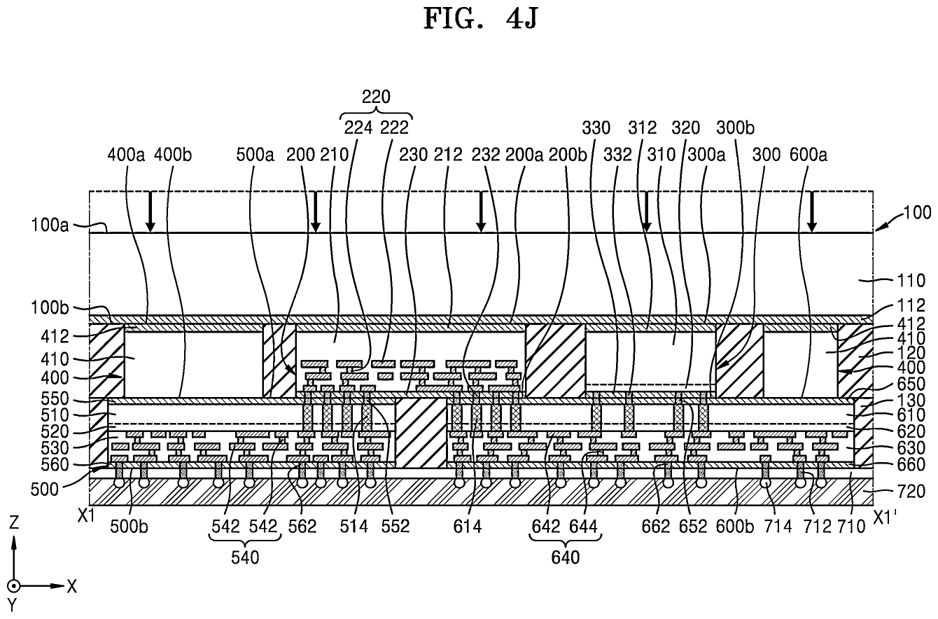

FIGS. 4A to 4J are cross-sectional views for describing a method S100 of manufacturing a semiconductor package, according to embodiments, and cross-sectional views illustrating a region corresponding to FIG. 1B, according to a process order. In FIGS. 4A to 4J, the same reference characters as those of FIGS. 1A and 1B denote the same member, and repeated descriptions thereof may be omitted. Hereinafter, the method S100 of manufacturing the semiconductor package, according to embodiments, is described in detail with reference to FIGS. 3 and 4A to 4J.

Referring to FIG. 4A, the bridge structure 200, the first semiconductor chip 300, and the plurality of dummy structures 400 may be bonded onto the carrier structure p100, in operation S110.

According to embodiments, the carrier structure p100 may include a carrier substrate p110 and a heat dissipation bonding dielectric layer 112 formed on one surface of the carrier substrate p110. According to embodiments, the bridge structure 200, the first semiconductor chip 300, and the plurality of dummy structures 400 may be disposed on the carrier structure p100. The first surface 200a of the bridge structure 200, the first surface 300a of the first semiconductor chip 300, and the first surface 400a of each of the plurality of dummy structures 400 may face the heat dissipation bonding dielectric layer 112 of the carrier structure p100. Accordingly, the heat dissipation bonding dielectric layer 112 of the carrier structure p110 may be, in the vertical direction (Z direction), in contact with the bridge-side bonding dielectric layer 212 of the bridge structure 200, the bonding dielectric layer 312 of the first semiconductor chip 300, and the dummy-side bonding dielectric layer 412 of each of the plurality of dummy structures 400.

Thereafter, in order to induce diffusion among dielectrics in contact with each other in the vertical direction, an annealing process may be performed for about 1 to 5 hours in a range of about 150° C. to about 500° C., to form dielectric-to-dielectric bonding. For example, the bridge structure 200, the first semiconductor chip 300, and the plurality of dummy structures 400 may be mounted on the carrier structure p100 through dielectric-to-dielectric bonding. In some embodiments, in the annealing process, pressure may be applied to the bridge structure 200, the first semiconductor chip 300, and the plurality of dummy structures 400 in a direction toward the carrier structure p100.

Referring to FIG. 4B, a first preliminary gap-fill insulating layer p120 may be formed to cover the result of FIG. 4A. According to embodiments, on the carrier structure p100, the first preliminary gap-fill insulating layer p120 may be sufficiently provided to fill around the bridge structure 200, fill around the first semiconductor chip 300, fill a space between the plurality of dummy structures 400, and to cover the second surface 200b of the bridge structure 200, the second surface 300b of the first semiconductor chip 300, and the second surface 400b of each of the plurality of dummy structures 400.

Referring to FIG. 4C, the first gap-fill insulating layer 120 may be formed in operation S120, by performing planarization until the second surface 200b of the bridge structure 200, the second surface 300b of the first semiconductor chip 300, and the second surface 400b of each of the plurality of dummy structures 400 in FIG. 4B is exposed. For example, the planarization process described above may include a grinding and chemical mechanical polishing/planarization (CMP) process.

According to embodiments, the second surface 200b of the bridge structure 200, the second surface 300b of the first semiconductor chip 300, the second surface 400b of each of the plurality of dummy structures 400, and a first surface 120u of the first gap-fill insulating layer 120 may be coplanar.

By the planarization process described above, the plurality of bridge-side conductive vias 232 and the bridge-side passivation layer 230 of the bridge structure 200 may be exposed, and the plurality of conductive vias 332 and the passivation layer 330 of the first semiconductor chip 300 may be exposed.

Referring to FIG. 4D, the second semiconductor chip 500 and the third semiconductor chip 600 may be bonded onto the result of FIG. 4C, in operation S130.

According to embodiments, the second semiconductor chip 500 may be arranged such that the plurality of first conductive vias 552 of the second semiconductor chip 500 is, in the vertical direction (Z direction), aligned and in contact with the bridge-side conductive vias 232 of the first group of the bridge structure 200. The first passivation layer 550 of the second semiconductor chip 500 may be in contact with the bridge-side passivation layer 230 in the vertical direction (Z direction).

According to embodiments, the third semiconductor chip 600 may be arranged such that the first group from among the plurality of first conductive vias 652 of the third semiconductor chip 600 is aligned and in contact with the second group from among the plurality of bridge-side conductive vias 232 of the bridge structure 200 in the vertical direction (Z direction) and that the second group from among the plurality of first conductive vias 652 of the of the third semiconductor chip 600 is aligned and in contact with the plurality of conductive vias 332 of the first semiconductor chip 300 in the vertical direction (Z direction). The first passivation layer 650 of the third semiconductor chip 600 may be in contact with the passivation layer 330 of the first semiconductor chip 300 in the vertical direction (Z direction).

Thereafter, an annealing process may be performed for about 1 to 5 hours in a range of about 150° C. to about 500° C., to form metal-to-metal bonding or dielectric-to-dielectric bonding. Accordingly, the second semiconductor chip 500 and the third semiconductor chip 600 may be mounted on the result of FIG. 4C. In this process, a dielectric-dielectric bonding may be performed between the first passivation layer 550 of the second semiconductor chip 500 and the first gap-fill insulating layer 120, and between the first passivation layer 650 of the third semiconductor chip 600 and the first gap-fill insulating layer 120.

Referring to FIG. 4E, a second preliminary gap-fill insulating layer p130 may be formed to cover the result of FIG. 4D. According to embodiments, the second preliminary gap-fill insulating layer p130 may be sufficiently provided to fill a space between the second semiconductor chip 500 and the third semiconductor chip 600, on the result of FIG. 4D, and to cover the second surface 500b of the second semiconductor chip 500 and the second surface 600b of the third semiconductor chip 600.

Referring to FIG. 4F, the first gap-fill insulating layer 120 may be formed in operation S140, by performing planarizing until the second surface 500b of the second semiconductor chip 500 and the second surface 600b of the third semiconductor chip 600 are exposed in FIG. 4E. According to embodiments, the second surface 500b of the second semiconductor chip 500, the second surface 600b of the third semiconductor chip 600, and a first surface 130u of the second gap-fill insulating layer 130 may be coplanar. By the planarization process described above, the plurality of second conductive vias 562 and the second passivation layer 560 of the second semiconductor chip 500 may be exposed, and the plurality of second conductive vias 662 and the second passivation layer 660 of the third semiconductor chip 600 may be exposed.

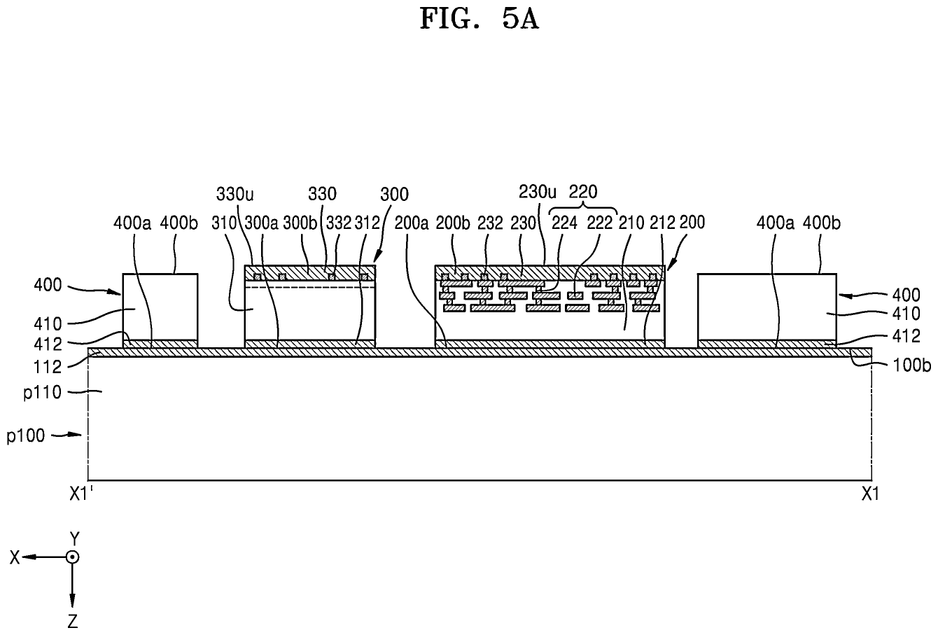

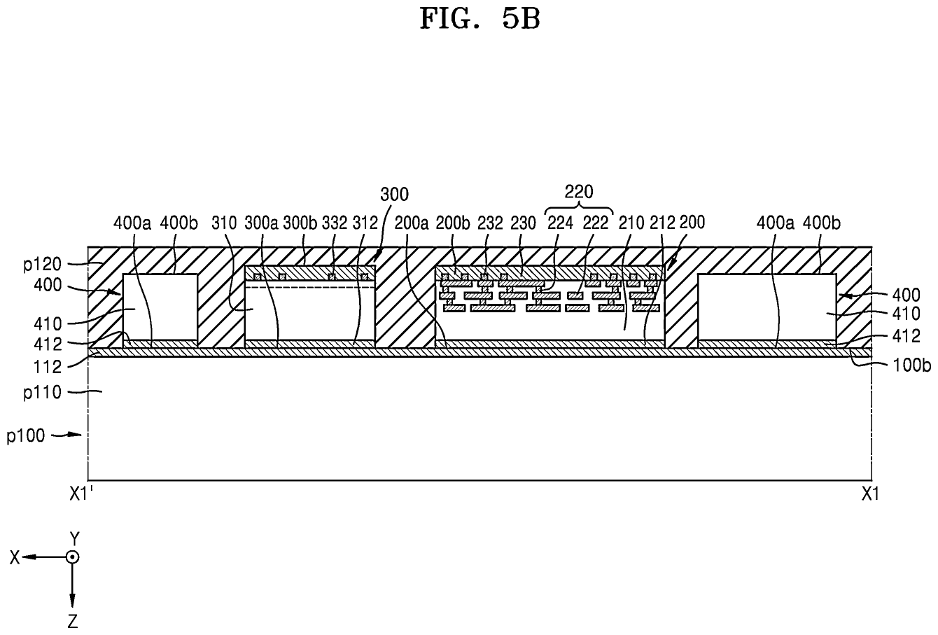

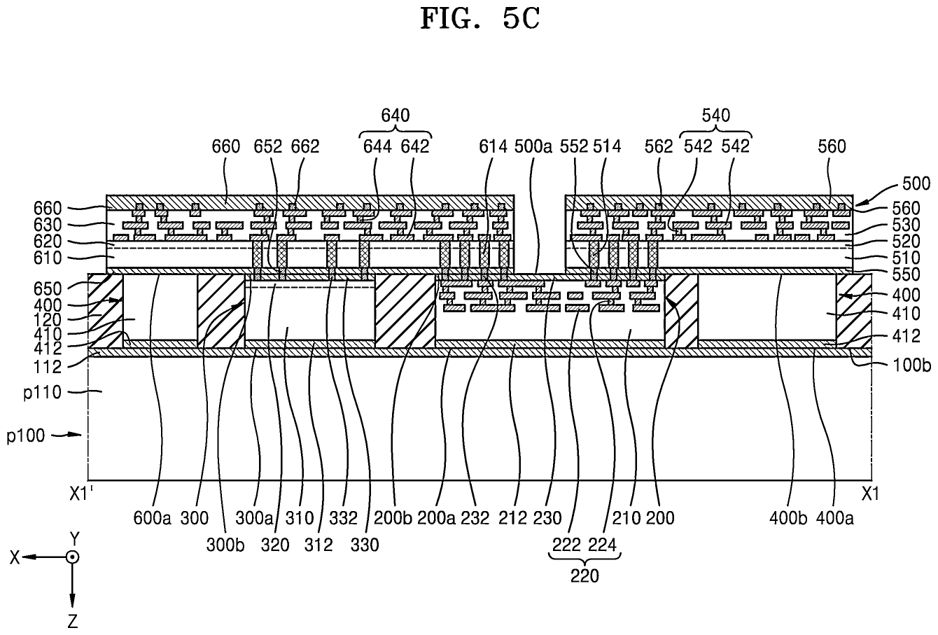

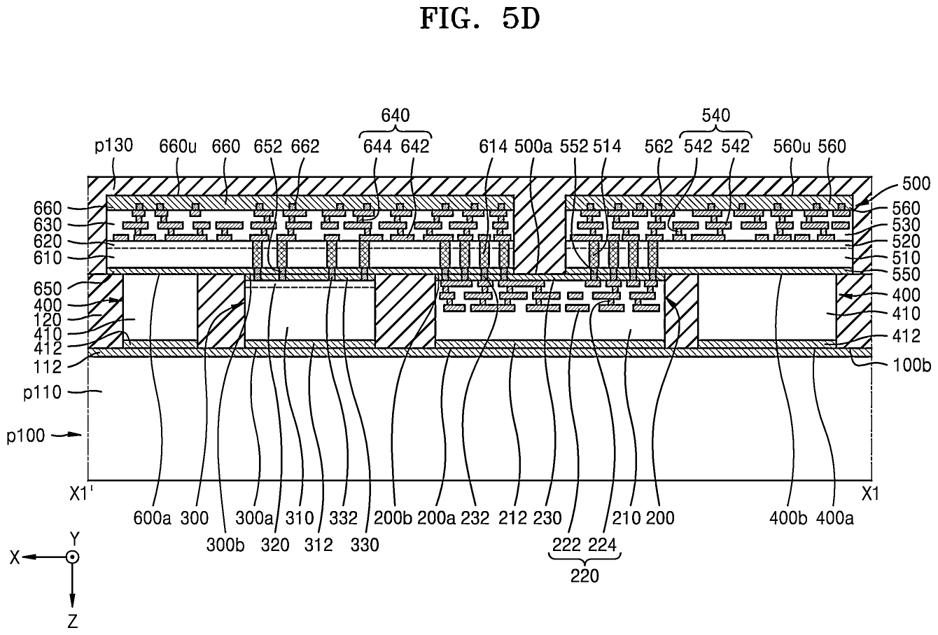

FIGS. 5A to 5D are cross-sectional views illustrating a method of manufacturing a semiconductor package, according to some embodiments. In FIGS. 5A to 5D, the same reference characters as those of FIGS. 4A to 4F denote the same member, and herein, repeated descriptions thereof may be omitted, and differences are mainly described.

Referring to FIGS. 5A and 5B, the bridge-side passivation layer 230 of the bridge structure 200 may be formed to cover the upper surfaces of the plurality of bridge-side conductive vias 232, and the passivation layer 330 of the first semiconductor chip 300 may be formed to cover the plurality of conductive vias 332 of the first semiconductor chip 300. Accordingly, in a process of bonding the bridge structure 200 and the first semiconductor chip 300 onto the carrier structure p100, damage to the plurality of bridge-side conductive vias 232 of the bridge structure 200 and the plurality of conductive vias 332 of the first semiconductor chip 300 may be prevented. In some embodiments, vertical levels of an upper surface 230u of the bridge-side passivation layer 230 and an upper surface 330u of the passivation layer 330 of the first semiconductor chip 300 may each be higher than vertical levels of the second surfaces 400b of the plurality of dummy structures 400.

Thereafter, the first preliminary gap-fill insulating layer p120 may be formed. The first preliminary gap-fill insulating layer p120 may be sufficiently formed to cover the upper surface of the bridge-side passivation layer 230 and the passivation layer 330 of the first semiconductor chip 300.

Thereafter, by planarizing the result of FIG. 5B, the plurality of bridge-side conductive vias 232 of the bridge structure 200 and the plurality of conductive vias 332 of the first semiconductor chip 300 may be exposed to form the result shown as an example in FIG. 4C.

Referring to FIGS. 5C and 5D, the second passivation layer 560 of the second semiconductor chip 500 may be formed to cover the plurality of second conductive vias 562, and the second passivation layer 660 of the third semiconductor chip 600 may be formed to cover the plurality of second conductive vias 662. Accordingly, in a process of bonding the second semiconductor chip 500 and the third semiconductor chip 600 on the result of FIG. 4C, damage to the plurality of second conductive vias 562 of the second semiconductor chip 500 and the plurality of second conductive vias 662 of the third semiconductor chip 600 may be prevented.

Thereafter, the second preliminary gap-fill insulating layer p130 may be formed to cover an upper surface 560u of the second passivation layer 560 of the second semiconductor chip 500 and an upper surface 660u of the second passivation layer 660 of the third semiconductor chip 600. Thereafter, by planarizing the result of FIG. 5D, the plurality of second conductive vias 562 of the second semiconductor chip 500 and the plurality of second conductive vias 662 of the third semiconductor chip 600 may be exposed to form the result shown as an example in FIG. 4F.

Referring to FIGS. 4G and 4H together with FIG. 4F, after forming the cover insulating layer on the result of FIG. 4F, a connection structure including the plurality of connection vias 712 and the plurality of connection bumps 714 may be formed in operation S150.

Referring to FIG. 4G, the cover insulating layer 710 may be formed on the result of FIG. 4F, to cover the second surface 500b of the second semiconductor chip 500, the second surface 600b of the third semiconductor chip 600, and the first surface 130u of the second gap-fill insulating layer 130.

According to embodiments, after a mask pattern exposing a portion of the cover insulating layer 710 is formed on the cover insulating layer 710, a portion of the cover insulating layer 710 may be removed with the mask pattern as an etch mask, to form a plurality of hole patterns passing through the cover insulating layer 710 in the vertical direction (Z direction). For example, through the plurality of hole patterns, the plurality of second conductive vias 562 of the second semiconductor chip 500 and the plurality of second conductive vias 662 of the third semiconductor chip 600 may be exposed. Thereafter, the plurality of connection vias 712 filling the plurality of hole patterns may be formed. In some embodiments, the mask pattern may be a photoresist pattern, but is not limited thereto. In some embodiments, the cover insulating layer 710 may include a PID, and a portion of the cover insulating layer 710 may be removed through a photo process to form the plurality of hole patterns. Thereafter, as shown in FIG. 4H, the plurality of connection bumps 714 may be formed on the plurality of connection vias 712 to be connected to the plurality of connection vias 712.

Referring to FIG. 4I, in the result of FIG. 4H, a release film 720 covering an upper surface of the cover insulating layer 710 and the plurality of connection bumps 714 may be formed.

In some embodiments, the release film 720 may include silicon-based polymer resin and fluorine-based polymer resin, but is not limited to the examples described above.

Referring to FIG. 4J, after flipping the result of FIG. 4I, the carrier substrate p110 of the carrier structure p100 may be processed to form the heat dissipation structure 100 including the heat dissipation substrate 110, in operation S160. For example, a portion of the carrier substrate p110 may be removed by considering a mounting space for the semiconductor package 10a.

Thereafter, the release film 720 may be removed to form the semiconductor package 10a as shown in FIG. 1B.

In the method S100 of manufacturing the semiconductor package, according to embodiments, the bridge structure 200, the first semiconductor chip 300, the second semiconductor chip 500, and the third semiconductor chip 600 may be formed on the carrier substrate p110, and then, the carrier substrate p110 may be used as the heat dissipation substrate 110 without being removed. In addition, according to the method S100 of manufacturing the semiconductor package, all of the semiconductor package 10a as a unit may be formed on one carrier structure p100. Accordingly, it is not necessary to use a plurality of carrier substrates, and therefore, costs of a manufacturing process for a semiconductor package may be reduced. In addition, the carrier substrate p110 in use may also be processed and used as the heat dissipation substrate 110, and therefore, costs may be reduced and structural/thermal stability of the semiconductor package 10a may be improved.

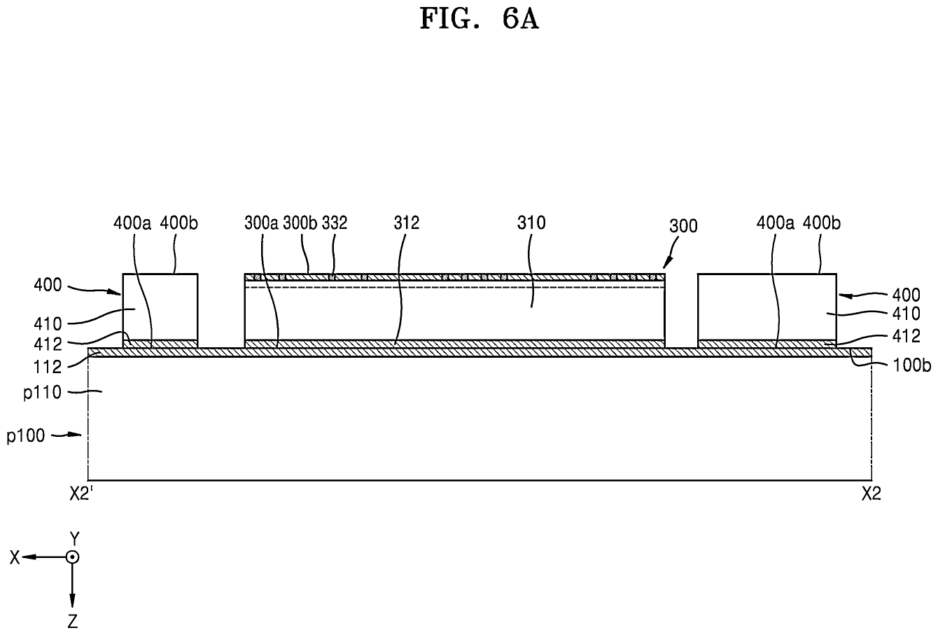

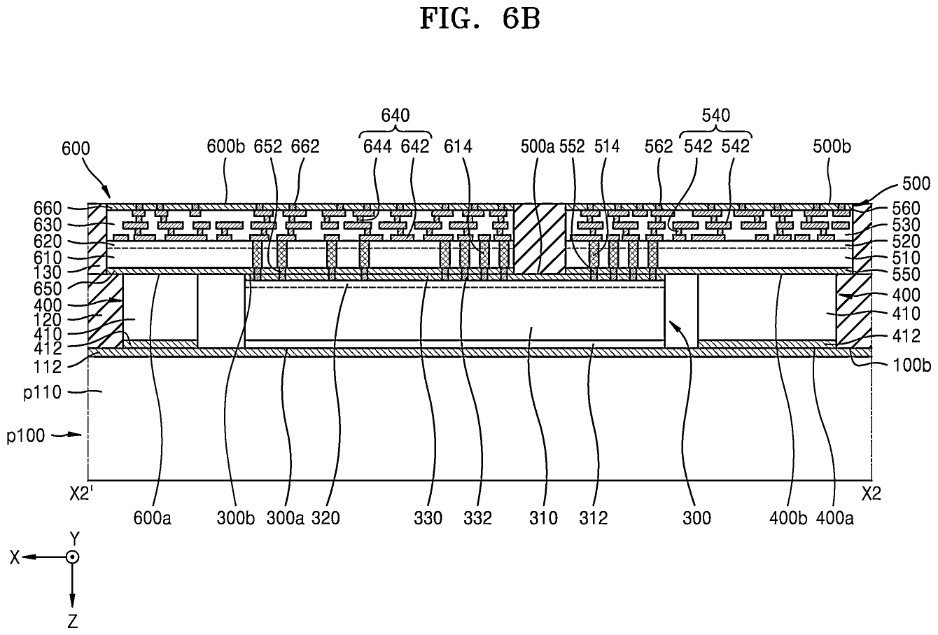

FIGS. 6A and 6B are cross-sectional views illustrating a method of manufacturing the semiconductor package 10b, according to some embodiments. In FIGS. 6A and 6B, the same reference characters as those of FIGS. 2A and 2B denote the same member, and repreated descriptions thereof may be omitted. Unlike the method S100 of manufacturing the semiconductor package 10b described with reference to FIGS. 4A to 4J, in the method of manufacturing the semiconductor package 10b described below, instead of the bridge structure 200, the first semiconductor chip 300 is formed as a bridge chip. In FIGS. 6A to 6B, the same reference characters as those of FIGS. 4A to 4J denote the same member, and repeated descriptions thereof may be omitted.

Referring to FIG. 6A, the first semiconductor chip 300 and the plurality of dummy structures 400 may be bonded onto the carrier structure p100.

After the bonding dielectric layer 312 of the first semiconductor chip 300 is arranged in contact with the heat dissipation bonding dielectric layer 112 of the carrier structure p100, dielectric-to-dielectric bonding may be formed between the heat dissipation bonding dielectric layer 112 and the bonding dielectric layer 312 through an annealing process. In this process, the dummy-side bonding dielectric layer 412 of each of the plurality of dummy structures 400 may form dielectric-to-dielectric bonding together with the heat dissipation bonding dielectric layer of the carrier structure p100.

Referring to FIG. 6B, in the result of FIG. 6A, after the first gap-fill insulating layer 120, the second semiconductor chip 500 and the third semiconductor chip 600 may be bonded onto the first semiconductor chip 300.

According to embodiments, the second semiconductor chip 500 may be arranged such that the plurality of first conductive vias 552 of the second semiconductor chip 500 is aligned and in contact with the first group from among the plurality of conductive vias 332 of the first semiconductor chip 300 in the vertical direction (Z direction). The first passivation layer 550 of the second semiconductor chip 500 may be in contact with the passivation layer 330 of the first semiconductor chip 300 in the vertical direction (Z direction).

According to embodiments, the third semiconductor chip 600 may be arranged such that the plurality of first conductive vias 652 of the third semiconductor chip 600 is aligned and in contact with the second group from among the plurality of conductive vias 332 of the first semiconductor chip 300 in the vertical direction (Z direction). The first passivation layer 650 of the third semiconductor chip 600 may be in contact with the passivation layer 330 of the first semiconductor chip 300 in the vertical direction (Z direction).

Thereafter, by performing an annealing process, metal-to-metal bonding and dielectric-to-dielectric bonding may be formed. For example, metal-to-metal bonding may be formed between the plurality of first conductive vias 552 of the second semiconductor chip 500 and the first group from among the plurality of conductive vias 332 of the first semiconductor chip 300 and between the plurality of first conductive vias 652 of the third semiconductor chip 600 and the second group from among the plurality of conductive vias 332 of the first semiconductor chip 300. For example, dielectric-to-dielectric bonding may be formed between the first passivation layer 550 of the second semiconductor chip 500 and the passivation layer 330 of the first semiconductor chip 300 and between the first passivation layer 650 of the third semiconductor chip 600 and the passivation layer 330 of the first semiconductor chip 300. In addition, dielectric-to-dielectric bonding may be formed between the first passivation layer 550 of the second semiconductor chip 500 and the first gap-fill insulating layer 120, and between the first passivation layer 650 of the third semiconductor chip 600 and the first gap-fill insulating layer 120.

Thereafter, the second gap-fill insulating layer 130 may be formed to form the result shown in FIG. 6B.

Thereafter, the cover insulating layer 710 covering the second surface 500b of the second semiconductor chip 500 and the second surface 600b of the third semiconductor chip 600 may be formed by performing the same process as that described with reference to FIGS. 4G to 4J, and then, the plurality of connection vias 712 passing through the cover insulating layer 710 may be formed, and the plurality of connection bumps 714 in contact with the plurality of connection vias 712 may be formed on the cover insulating layer 710. Thereafter, the release film 720 covering the cover insulating layer 710 and the plurality of connection bumps 714 may be formed, and then, the carrier substrate p110 may be processed to form the heat dissipation substrate 110, to form the semiconductor package 10b shown in FIG. 2B.

While non-limiting example embodiments of the present disclosure have been particularly shown and described with reference to the drawings, it will be understood that various changes in form and details may be made therein without departing from the spirit and scope of the present disclosure.

What is claimed is:

1. A method of manufacturing a semiconductor package, the method comprising:
bonding a first semiconductor chip and a bridge structure onto a carrier structure;
bonding a second semiconductor chip and a third semiconductor chip onto the bridge structure, the second semiconductor chip and the third semiconductor chip being apart from each other in a horizontal direction; and
forming a plurality of connection bumps on the second semiconductor chip and the third semiconductor chip.

2. The method of claim 1, wherein each of the bonding between the bridge structure and the second semiconductor chip and the bonding between the bridge structure and the third semiconductor chip is performed through a combination of dielectric-to-dielectric bonding and metal-to-metal bonding.

3. The method of claim 1, wherein each of the bonding between the carrier structure and the first semiconductor chip and the bonding between the carrier structure and the bridge structure is performed through dielectric-to-dielectric bonding.

4. The method of claim 1, further comprising, before the bonding of the second semiconductor chip and the third semiconductor chip:
forming a first preliminary gap-fill insulating layer on the first semiconductor chip and the bridge structure; and
forming a first gap-fill insulating layer by planarizing the first preliminary gap-fill insulating layer.

5. The method of claim 4, wherein, after the bonding of the second semiconductor chip and the third semiconductor chip:
forming a second preliminary gap-fill insulating layer on the second semiconductor chip and the third semiconductor chip; and
forming a second gap-fill insulating layer by planarizing the second preliminary gap-fill insulating layer.

6. The method of claim 4, further comprising bonding the first gap-fill insulating layer to the second semiconductor chip and the third semiconductor chip by dielectric-to-dielectric bonding.

7. The method of claim 1, further comprising forming a heat dissipation structure by removing a portion of the carrier structure.

8. The method of claim 1, wherein the bonding of the first semiconductor chip and the bridge structure comprises bonding at least one dummy structure onto the carrier structure.

9. The method of claim 8, wherein the bonding of the at least one dummy structure comprises bonding the at least one dummy structure between the carrier structure and the second semiconductor chip and between the carrier structure and the third semiconductor chip.

10. The method of claim 8, wherein the bonding between the at least one dummy structure and the carrier structure is performed using dielectric-to-dielectric bonding.

11. A method of manufacturing a semiconductor package, the method comprising:
bonding a bridge chip and a plurality of dummy structures onto a carrier structure;
connecting a first semiconductor chip to a second semiconductor chip through the bridge chip by bonding the first semiconductor chip and the second semiconductor chip onto the bridge chip;
forming a cover insulating layer that covers the first semiconductor chip and the second semiconductor chip;
forming a plurality of connection vias that pass through the cover insulating layer to contact the first semiconductor chip or the second semiconductor chip; and
forming a plurality of connection bumps on the cover insulating layer, the plurality of connection bumps being in contact with the plurality of connection vias.

12. The method of claim 11, wherein the plurality of dummy structures are around the bridge chip, and
at least some of the plurality of dummy structures overlap the first semiconductor chip and the second semiconductor chip, in a vertical direction, and contact the first semiconductor chip and the second semiconductor chip.

13. The method of claim 11, further comprising forming a gap-fill insulating layer between the carrier structure and the cover insulating layer, the gap-fill insulating layer surrounding the bridge chip, the plurality of dummy structures, the first semiconductor chip, and the second semiconductor chip.

14. The method of claim 11, wherein the carrier structure includes:
a carrier substrate; and
a heat dissipation bonding dielectric layer on the carrier substrate,
the bridge chip includes:
a first bonding dielectric layer facing the heat dissipation bonding dielectric layer;
a bridge substrate on the first bonding dielectric layer;
a first passivation layer on the bridge substrate; and
a plurality of first conductive vias passing through the first passivation layer in a vertical direction, and
wherein the bonding the bridge chip onto the carrier structure comprises bonding the carrier structure and the bridge chip together through dielectric-dielectric bonding between the heat dissipation bonding dielectric layer and the first bonding dielectric layer.

15. The method of claim 14, wherein the first semiconductor chip includes:
a first semiconductor substrate having a first active surface and a first inactive surface, the first inactive surface being opposite to the first active surface and facing the carrier structure;
a second passivation layer on the first inactive surface of the first semiconductor substrate and in contact with the first passivation layer of the bridge chip; and
a plurality of second conductive vias passing through the second passivation layer and aligned in the vertical direction with and in contact with a first group of first conductive vias from among the plurality of first conductive vias of the bridge chip, and
wherein the bonding of the first semiconductor chip onto the bridge chip comprises bonding the bridge chip and the first semiconductor chip through:
dielectric-to-dielectric bonding between the first passivation layer of the bridge chip and the second passivation layer of the first semiconductor chip; and
metal-to-metal bonding between the first group from among the plurality of first conductive vias of the bridge chip and the plurality of second conductive vias of the first semiconductor chip.

16. The method of claim 15, wherein the second semiconductor chip includes:
a second semiconductor substrate having a second active surface and a second inactive surface, the second inactive surface being opposite to the second active surface and facing the carrier substrate;
a third passivation layer on the second inactive surface of the second semiconductor substrate and in contact with the first passivation layer of the bridge chip; and
a plurality of third conductive vias passing through the third passivation layer and aligned in the vertical direction with and contacting a second group of first conductive vias from among the plurality of first conductive vias, and
wherein the bonding of the second semiconductor chip onto the bridge chip comprises bonding the bridge chip and the second semiconductor chip through:
dielectric-to-dielectric bonding between the first passivation layer of the bridge chip and the third passivation layer of the second semiconductor chip; and
metal-to-metal bonding between the second group from among the plurality of first conductive vias of the bridge chip and the plurality of third conductive vias of the second semiconductor chip.

17. The method of claim 11, wherein
the carrier structure includes:
a carrier substrate; and
a heat dissipation bonding dielectric layer on the carrier substrate,
each of the plurality of dummy structures includes:
a dummy-side bonding dielectric layer in contact with the heat dissipation bonding dielectric layer, on the heat dissipation bonding dielectric layer; and
a dummy substrate on the dummy-side bonding dielectric layer, and
the bonding the plurality of dummy structures comprises bonding the carrier structure to the plurality of dummy structures through dielectric-dielectric bonding between the heat dissipation bonding dielectric layer and the dummy-side bonding dielectric layer.

18. A method of manufacturing a semiconductor package, the method comprising:
bonding a first semiconductor chip, a bridge structure, and a plurality of dummy structures onto a carrier structure, the plurality of dummy structures being around the first semiconductor chip and the bridge structure;
forming a first preliminary gap-fill insulating layer that covers the first semiconductor chip, the bridge structure, and the plurality of dummy structures;
forming a first gap-fill insulating layer that exposes the first semiconductor chip, the bridge structure, and the plurality of dummy structures, by planarizing the first preliminary gap-fill insulating layer;
bonding, onto the bridge structure, a second semiconductor chip and a third semiconductor chip, such that the second semiconductor chip is connected to the third semiconductor chip via the bridge structure;
forming a second preliminary gap-fill insulating layer that covers the second semiconductor chip and the third semiconductor chip;
forming a second gap-fill insulating layer that exposes the second semiconductor chip and the third semiconductor chip, by planarizing the second preliminary gap-fill insulating layer;
forming a cover insulating layer on the second semiconductor chip, the third semiconductor chip, and the second gap-fill insulating layer;
forming a plurality of connection vias that pass through the cover insulating layer and are connected to the second semiconductor chip or the third semiconductor chip;
forming a plurality of connection bumps on the cover insulating layer, the plurality of connection bumps being respectively connected to the plurality of connection vias; and
forming a heat dissipation structure by processing the carrier structure.

19. The method of claim 18, wherein each of the bonding between the bridge structure and the second semiconductor chip and the bonding between the bridge structure and the third semiconductor chip is performed through a combination of dielectric-to-dielectric bonding and metal-to-metal bonding.

20. The method of claim 18, wherein each of the bonding between the carrier structure and the bridge structure, the bonding between the carrier structure and the first semiconductor chip, and the bonding between the carrier structure and the plurality of dummy structures is performed through dielectric-to-dielectric bonding.
